(19) United States
(12) Patent Application Publication
(10) Pub. No.: US 2025/0201755 A1
(43) Pub. Date: Jun. 19, 2025

(54) SEMICONDUCTOR PACKAGE

(71) Applicant: Samsung Electronics Co., Ltd., Suwon-si (KR)

(72) Inventors: Kihong Jeong, Suwon-si (KR); Dongok Kwak, Suwon-si (KR); Cheolwoo Lee, Suwon-si (KR)

(21) Appl. No.: 18/967,816

(22) Filed: Dec. 4, 2024

(30) Foreign Application Priority Data
Dec. 18, 2023 (KR) 10-2023-0185071

(51) Int. Cl. H01L 23/00; H01L 25/065

(52) U.S. Cl. CPC H01L 24/48; H01L 24/49; H01L 25/0657; H01L 2224/4801; H01L 2224/4805; H01L 2224/48145; H01L 2224/48227; H01L 2224/49051; H01L 2224/49109; H01L 2225/06506; H01L 2225/0651; H01L 2225/06562

(57) ABSTRACT

A semiconductor package includes a package substrate, a stack structure on the package substrate and including a plurality of semiconductor chips stacked sequentially and offset, and a plurality of chip selection wires configured to respectively electrically connect the package substrate to the plurality of semiconductor chips of the stack structure, wherein each of the plurality of semiconductor chips includes a plurality of chip selection pads, each of the plurality of chip selection wires extends from the package substrate to one of the plurality of semiconductor chips along side and top surfaces of the stack structure, and extension lengths of the plurality of chip selection wires are different from each other.

### CROSS-REFERENCE TO RELATED APPLICATION

This application is based on and claims priority under 35 U.S.C. § 119 to Korean Patent Application No. 10-2023-0185071, filed on Dec. 18, 2023, in the Korean Intellectual Property Office, the disclosure of which is incorporated by reference herein in its entirety.

### BACKGROUND

The inventive concept relates to a semiconductor package, and more particularly, to a semiconductor package including a plurality of offset-stacked semiconductor chips.

In multi-chip packages having a plurality of semiconductor chips embedded therein, as the numbers of semiconductor chips and input/output (I/O) channels is increased for high capacity and performance, the number of vertically stacked chips may be reduced by arranging the semiconductor chips in parallel. However, when the semiconductor chips are arranged in parallel, an overhang portion sags because of a size difference between the same or different types of chips. When the numbers of chips arranged in parallel is symmetrical, there is a limit to reducing the thickness of a package.

### SUMMARY

The inventive concept provides a semiconductor package wherein the signal distance between stacked semiconductor chips is reduced.

The inventive concept also provides a semiconductor package with reduced cost obtained by simplifying processes.

The inventive concept is not limited to those mentioned above, and the inventive concept that has not been mentioned will be clearly understood by one of skill in the art from the description below.

According to an aspect of the inventive concept, there is provided a semiconductor package including a package substrate, a stack structure on the package substrate and including a plurality of semiconductor chips stacked sequentially and offset from each other, and a plurality of chip selection wires configured to respectively electrically connect the package substrate to the plurality of semiconductor chips of the stack structure, wherein each of the plurality of semiconductor chips includes a plurality of chip selection pads, each of the plurality of chip selection wires extends from the package substrate to one of the plurality of semiconductor chips along side and top surfaces of the stack structure, and extension lengths of the plurality of chip selection wires are different from each other.

According to another aspect of the inventive concept, there is provided a semiconductor package including a package substrate, a lower stack structure on the package substrate and including a plurality of lower semiconductor chips stacked sequentially and offset in a first horizontal direction, an upper stack structure on the lower stack structure and including a plurality of upper semiconductor chips stacked sequentially and offset in an opposite direction to the first horizontal direction, a support chip on the package substrate and in contact with a bottom surface of the upper stack structure, a plurality of lower chip selection wires configured to electrically connect the package substrate to the plurality of lower semiconductor chips of the lower stack structure, and a plurality of upper chip selection wires configured to electrically connect the package substrate to the plurality of upper semiconductor chips of the upper stack structure, wherein the upper stack structure is offset from the lower stack structure in the first horizontal direction, each of the plurality of lower chip selection wires extends from the package substrate to one of the plurality of lower semiconductor chips along side and top surfaces of the lower stack structure, and each of the plurality of upper chip selection wires extends from the package substrate to one of the plurality of upper semiconductor chips along an outer surface of the support chip and side and top surfaces of the upper stack structure.

According to still another aspect of the inventive concept, there is provided a semiconductor package including a package substrate, a stack structure on the package substrate and including a plurality of semiconductor chips stacked sequentially and offset in a first horizontal direction, an insulating cover on a top surface of the stack structure, and a plurality of chip selection wires configured to electrically connect the package substrate to the plurality of semiconductor chips of the stack structure, wherein each of the plurality of semiconductor chips includes a plurality of chip selection pads on a top surface thereof, the insulating cover covers at least one of the plurality of chip selection pads of the plurality of semiconductor chips, a top surface of the insulating cover is in contact with at least one of the plurality of chip selection wires, and each of the plurality of chip selection wires extends from the package substrate to one of the plurality of semiconductor chips along side and top surfaces of the stack structure.

According to a further aspect of the inventive concept, there is provided a semiconductor package including a package substrate, a stack structure on the package substrate and including a plurality of semiconductor chips stacked sequentially and offset in a first horizontal direction, and a plurality of chip selection wires configured to electrically connect the package substrate to the plurality of semiconductor chips of the stack structure, wherein each of the plurality of chip selection wires extends from the package substrate to one of the plurality of semiconductor chips along side and top surfaces of the stack structure, each of the plurality of semiconductor chips includes a plurality of chip selection pads on a top surface thereof, the plurality of chip selection pads being spaced apart from each other in a second horizontal direction that is perpendicular to the first horizontal direction, a first chip selection wire among the plurality of chip selection wires includes a first portion and a second portion extending in a different direction than the first portion, and in a plan view, the first portion extends in the first horizontal direction and the second portion extends in a direction inclined in the second horizontal direction with respect to the first horizontal direction.

### BRIEF DESCRIPTION OF THE DRAWINGS

Embodiments will be more clearly understood from the following detailed description taken in conjunction with the accompanying drawings in which:

FIG. 1 is a schematic perspective view of a semiconductor package, according to an example embodiment;

FIG. 2 is a schematic plan view of the semiconductor package of FIG. 1;

FIG. 3 is a schematic cross-sectional view of the semiconductor package of FIG. 2, taken along line A-A′ in FIG. 2;

FIG. 4 is a schematic enlarged plan view of a chip selection pad portion of the semiconductor package of FIG. 2, according to an example embodiment;

FIG. 5 is a schematic enlarged plan view of a chip selection pad portion of a semiconductor package, according to an example embodiment;

FIG. 6 is a schematic enlarged plan view of a chip selection pad portion of a semiconductor package, according to an example embodiment;

FIG. 7 is a schematic perspective view of a semiconductor package, according to an example embodiment;

FIG. 8 is a schematic plan view of the semiconductor package of FIG. 7;

FIG. 9 is a schematic cross-sectional view of the semiconductor package of FIG. 8, taken along line B-B′ in FIG. 8;

FIG. 10 is a schematic cross-sectional view of a semiconductor package, taken along line B-B′ in FIG. 8, according to an example embodiment;

FIG. 11 is a schematic perspective view of a semiconductor package, according to an example embodiment;

FIG. 12 is a schematic cross-sectional view of the semiconductor package of FIG. 11, taken along line C-C′ in FIG. 11;

FIG. 13 is a schematic enlarged plan view of a chip selection pad portion of the semiconductor package of FIG. 12;

FIG. 14 is a schematic enlarged plan view of a chip selection pad portion of a semiconductor package, according to an example embodiment;

FIG. 15 is a schematic perspective view of a semiconductor package, according to an example embodiment;

FIG. 16 is a schematic plan view of the semiconductor package of FIG. 15;

FIG. 17 is a schematic enlarged plan view of a chip selection pad portion of the semiconductor package of FIG. 16; and

FIG. 18 is a schematic enlarged plan view of a chip selection pad portion of a semiconductor package, according to an example embodiment.

### DETAILED DESCRIPTION OF THE EMBODIMENTS

As embodiments allows for various changes and numerous embodiments, some embodiments will be illustrated in the drawings and described in detail in the written description. However, this is not intended to limit embodiments to particular modes of practice. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

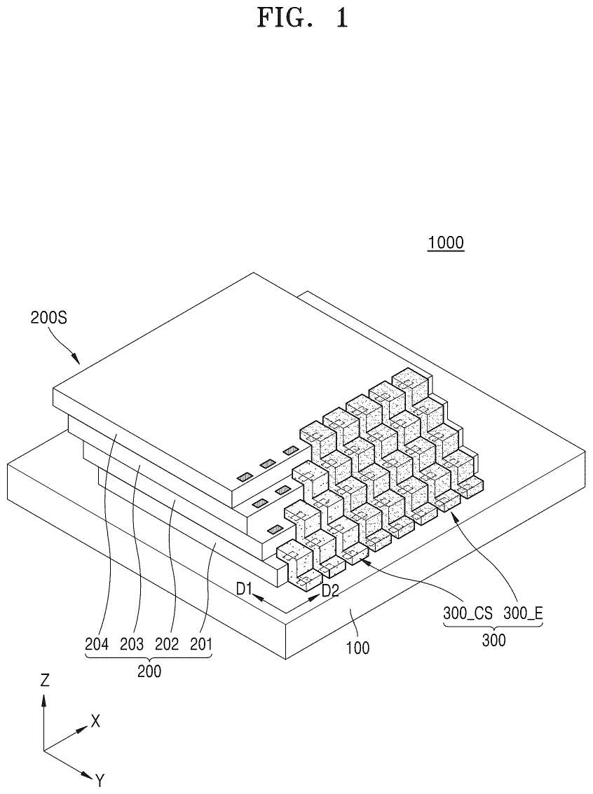

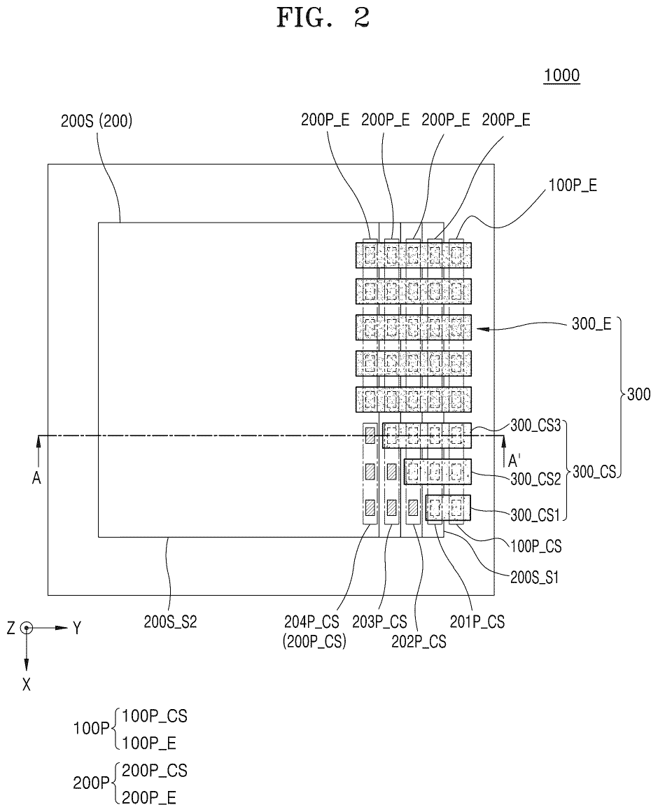

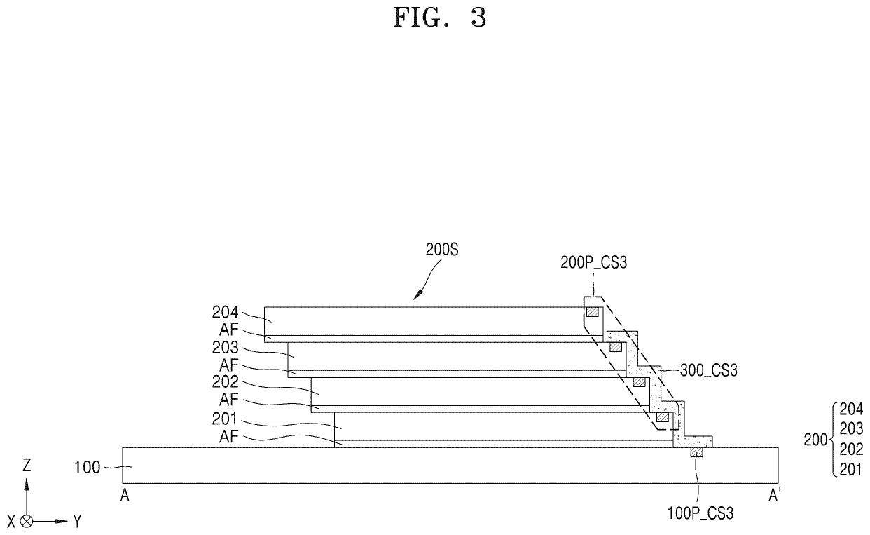

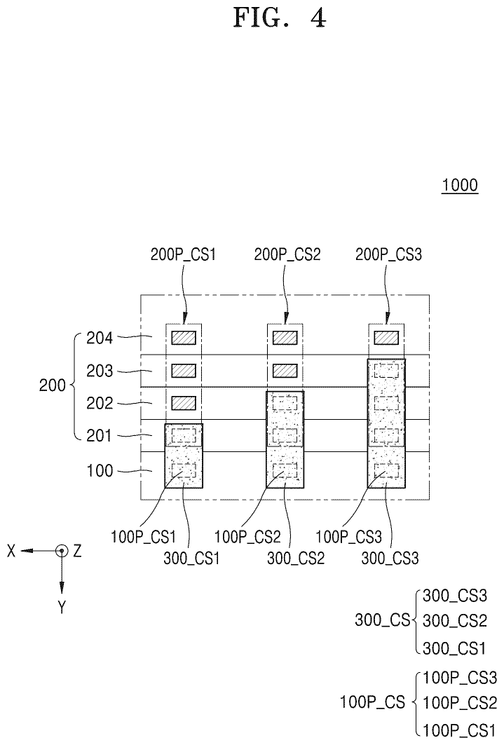

FIG. 1 is a schematic perspective view of a semiconductor package 1000 according to an example embodiment. FIG. 2 is a schematic plan view of the semiconductor package 1000 of FIG. 1. FIG. 3 is a schematic cross-sectional view of the semiconductor package 1000 of FIG. 2, taken along line A-A′ in FIG. 2. FIG. 4 is a schematic enlarged plan view of a chip selection pad portion of the semiconductor package 1000 of FIG. 2.

Referring to FIGS. 1 to 4, the semiconductor package 1000 may include a package substrate 100, a stack structure 200S, and a plurality of wires 300.

In embodiments, the semiconductor package 1000 may be a multi-chip package (MCP) including different types of semiconductor chips. The semiconductor package 1000 may be a system-in-package (SIP), in which a plurality of semiconductor chips are stacked or arranged in a single package to have a single independent function.

Unless stated otherwise, a direction that is parallel with the top surface of the package substrate 100 is defined as a first direction (an X direction), a direction that is perpendicular to the top surface of the package substrate 100 is defined as the vertical direction (a Z direction), and a direction that is perpendicular to the first direction (the X direction) and the vertical direction (the Z direction) is defined as a second direction (a Y direction). A direction combining the first direction (the X direction) and the second direction (the Y direction) is defined as a horizontal direction.

The package substrate 100 may have a top surface and a bottom surface, which are opposite to each other. For example, the package substrate 100 may include a printed circuit board (PCB), a flexible substrate, a tape substrate, or the like. The package substrate 100 may include a multi-layer circuit board including a via and various circuits therein. The package substrate 100 may include internal wires as channels electrically connecting a logic chip to memory chips.

A plurality of substrate pads 100P may be on the top surface of the package substrate 100. The substrate pads 100P may be connected to internal wires. The internal wires may extend on the top surface of the package substrate 100 and/or inside the package substrate 100.

The substrate pads 100P of the package substrate 100 may include a signal substrate pad 100P_E and a plurality of chip selection substrate pads 100P_CS. The signal substrate pad 100P_E may be electrically connected to a signal pad 200P_E among a plurality of pads 200P of a plurality of semiconductor chips 200 through a signal wire 300_E. The chip selection substrate pads 100P_CS may be electrically connected to a plurality of chip selection pads 200P_CS among the pads 200P of the semiconductor chips 200 through a plurality of chip selection wires 300_CS.

Although several substrate pads are illustrated in the drawings, the number and the arrangement of substrate pads are just shown as examples and embodiments are not limited thereto.

In some embodiments, external contact pads for providing electrical signals may be formed on the bottom surface of the package substrate 100. External connection members, such as solder balls, for electrical connection to an external device may be arranged on the external contact pads of the package substrate 100.

The stack structure 200S may be located on the package substrate 100. The stack structure 200S may include the semiconductor chips 200. The semiconductor chips 200 may be stacked sequentially offset in a first horizontal direction D1. For example, the stack structure 200S may have a cascade or stair structure.

In some embodiments, the semiconductor chips 200 may have the same length in a second horizontal direction D2 that is perpendicular to the first horizontal direction D1. For example, side surfaces of the stack structure 200S, which are spaced apart from each other in the second horizontal direction D2, may be flat, and side surfaces of the stack structure 200S, which are spaced apart from each other in the first horizontal direction D1, may have steps due to an offset stack of the semiconductor chips 200.

Each of the semiconductor chips 200 may include a memory semiconductor chip including a memory cell. For example, the memory cell may include a non-volatile memory cell, such as a flash memory, phase-change random access memory (PRAM) cell, a magnetoresistive RAM (MRAM) cell, a ferroelectric RAM (FeRAM) cell, or a resistive RAM (RRAM) cell. In some embodiments, the memory cell may include a volatile memory cell, such as a dynamic RAM (DRAM) cell or a static RAM (SRAM) cell.

In some embodiments, the semiconductor chips 200 may be sequentially stacked through an adhesive member AF. For example, the adhesive member AF may be between two adjacent semiconductor chips 200 or between a bottommost one of the semiconductor chips 200 and the package substrate 100. In example embodiments, when the adhesive member AF is between two adjacent semiconductor chips 200, the adhesive member AF may contact a lower surface of one of the semiconductor chips 200 and a top surface of the other of the semiconductor chips 200. When the adhesive member AF is between the bottommost one of the semiconductor chips 200 and the package substrate 100, the adhesive member AF may contact a lower surface of the bottommost one of the semiconductor chips 200 and a top surface of the package substrate 100. For example, the adhesive member AF may include an adhesive film such as a direct adhesive film (DAF).

Each of the semiconductor chips 200 may include a plurality of pads 200P. The pads 200P may be on the top surface of each of the semiconductor chips 200. The pads 200P may be exposed to the outside. In example embodiments, top surfaces of each of the pads 200P may be coplanar with top surfaces of the semiconductor chips 200 on which the pads 200P are provided. For example, the semiconductor chips 200 may be offset from each other in the first horizontal direction D1 such that the top surfaces of the pads 200P are exposed.

The pads 200P of each of the semiconductor chips 200 may be spaced apart from each other in the second horizontal direction D2. For example, the pads 200P may be arranged along a first side surface of each of the semiconductor chips 200. In some embodiments, the pads 200P may be arranged on the top surface of each of the semiconductor chips 200 in a straight line or a zigzag along the first side surface of each of the semiconductor chips 200 in the second horizontal direction D2.

In some embodiments, the pads 200P may include a plurality of chip selection pads 200P_CS and a signal pad 200P_E. Each of the semiconductor chips 200 may have a unique identification signal through the chip selection pads 200P_CS thereof. A controller (not shown) may identify each of the semiconductor chips 200 by analyzing the unique identification signal of each of the semiconductor chips 200. Each of the semiconductor chips 200 may input and/or output signals and/or power through the signal pad 200P_E.

The wires 300 may electrically connect the package substrate 100 to the stack structure 200S. Each of the wires 300 may extend from the package substrate 100 to one of the semiconductor chips 200 along the side and top surfaces of the stack structure 200S. The wires 300 may be in contact with an outer surface of the stack structure 200S and may extend from the package substrate 100 to the semiconductor chips 200. In some embodiments, the wires 300 may extend in the first horizontal direction D1 along the top surface of the stack structure 200S and in the vertical direction (the Z direction) along the side surface of the stack structure 200S.

In some embodiments, the stack structure 200S may include a first side surface 200S_S1 and a second side surface 200S_S2 adjacent to the first side surface 200S_S1. The wires 300 may extend along the first side surface 200S_S1 and the top surface of the stack structure 200S. In some embodiments, the wires 300 may conformally extend along the side and top surfaces of the stack structure 200S.

The wires 300 may include a plurality of chip selection wires 300_CS and a signal wire 300_E. The chip selection wires 300_CS may electrically connect the chip selection substrate pads 100P_CS to the chip selection pads 200P_CS, and the signal wire 300_E may electrically connect the signal substrate pad 100P_E to the signal pad 200P_E.

A signal level of pads 200P and substrate pads 100P, which are electrically connected to the wires 300, may be referred to as “1” and a signal level of pads 200P and substrate pads 100P, which are not electrically connected to the wires 300, may be referred to as “0”.

The signal wire 300_E may extend from the package substrate 100 to the topmost semiconductor chip of the stack structure 200S. The chip selection wires 300_CS may be shorter than the signal wire 300_E. For example, each of the chip selection wires 300_CS may extend from the package substrate 100 to one of the semiconductor chips 200 except for the topmost semiconductor chip of the stack structure 200S.

In some embodiments, one end of each of the chip selection wires 300_CS may be respectively on the top surfaces of different semiconductor chips among the semiconductor chips 200 and the other ends of the chip selection wires 300_CS may be on the top surface of the package substrate 100.

In some embodiments, a semiconductor chip having on a top surface thereof an end of one of the chip selection wires 300_CS may be referred to as a target semiconductor chip of one of the chip selection wires 300_CS. Each of the chip selection wires 300_CS may be electrically connected to all semiconductor chips 200 between the target semiconductor chip thereof and the package substrate 100. For example, each of the chip selection wires 300_CS may extend in contact with the top and side surfaces of the stack structure 200S from the package substrate 100 to the target semiconductor chip thereof and may thus be electrically connected to the target semiconductor chip and any semiconductor chip between the target semiconductor chip and the package substrate 100.

In some embodiments, the semiconductor chips 200 may be electrically connected to different numbers of chip selection wires 300_CS. For example, the chip selection wires 300_CS may have different target semiconductor chips, and accordingly, the semiconductor chips 200 may be electrically connected to different numbers of chip selection wires 300_CS.

In some embodiments, the number of chip selection wires 300_CS electrically connected to each of the semiconductor chips 200 may increase toward the bottom of the stack structure 200S.

For example, a first semiconductor chip 201 among the semiconductor chips 200 may be electrically connected to a chip selection wire 300_CS, of which an end is on the top surface of the first semiconductor chip 201, and any other chip selection wire 300_CS, of which an end is on the top surface of a semiconductor chip above the first semiconductor chip 201. Accordingly, the number of chip selection wires 300_CS electrically connected to each of the semiconductor chips 200 may increase toward the package substrate 100.

The chip selection wires 300_CS may have different extension lengths. For example, the higher the vertical level of an end of each of the chip selection wires 300_CS, the greater the extension length of each of the chip selection wires 300_CS. The semiconductor chips 200 may be sequentially stacked and may thus have different vertical levels. The vertical level of an end of each of the chip selection wires 300_CS may be determined by the vertical level of the top surface of a semiconductor chip, on which the end of each of the chip selection wires 300_CS is located. Accordingly, when one ends of the chip selection wires 300_CS are respectively located on the top surfaces of different semiconductor chips, the extension lengths of the chip selection wires 300_CS may be different.

In some embodiments, the extension length of each of the chip selection wires 300_CS may decrease toward the second side surface 200S_S2 of the stack structure 200S. For example, as each of the chip selection wires 300_CS is closer to the second side surface 200S_S2 of the stack structure 200S, each of the chip selection wires 300_CS may be located on the top surface of a lower one of the semiconductor chips 200.

In some embodiments, the chip selection wires 300_CS may be spaced apart from each other in the second horizontal direction D2. The chip selection wires 300_CS may be respectively and electrically connected to different chip selection pads 200P_CS of one of the semiconductor chips 200. In other words, two or more chip wires 300_CS may not be connected to each of the chip selection pads 200P_CS of one semiconductor chip. For example, the chip selection pads 200P_CS of the bottommost one of the semiconductor chips 200 may be respectively and electrically connected to different chip selection wires 300_CS.

In some embodiments, the number of chip selection pads 200P_CS included in each of the semiconductor chips 200 may be one less than the number of semiconductor chips 200 of the stack structure 200S. For example, when the number of semiconductor chips 200 of the stack structure 200S is N (where N is a natural number of at least 2), the number of chip selection pads 200P_CS included in each of the semiconductor chips 200 may be N−1. In some embodiments, the number of chip selection substrate pads 100P_CS may be N−1.

In some embodiments, the number of chip selection wires 300_CS may be one less than the number of semiconductor chips 200 of the stack structure 200S. For example, when the number of semiconductor chips 200 of the stack structure 200S is N (where N is a natural number of at least 2), the number of chip selection wires 300_CS may be N−1.

In some embodiments, the bottommost one of the semiconductor chips 200 may be electrically connected to N−1 chip selection wires 300_CS. As the semiconductor chips 200 go up layer by layer from the bottommost semiconductor chip 200, the number of chip selection wires 300_CS electrically connected to each of the semiconductor chips 200 may decrease one by one. Accordingly, the number of chip selection wires 300_CS electrically connected to the bottommost one of the semiconductor chips 200 may be N−1 and the number of chip selection wires 300_CS electrically connected to the topmost one of the semiconductor chips 200 may be 0.

For example, the semiconductor chips 200 may include the first semiconductor chip 201 and a second semiconductor chip 202 on the first semiconductor chip 201. The number of chip selection wires 300_CS electrically connected to the second semiconductor chip 202 may be one less than the number of chip selection wires 300_CS electrically connected to the first semiconductor chip 201.

When the package substrate 100 is electrically connected to the stack structure 200S through the wires 300, the signal distance between the stack structure 200S and the package substrate 100 may decrease, and accordingly, signal accuracy may increase. In addition, the manufacturing cost of the semiconductor package 1000 may be reduced by simplifying the process of forming the chip selection wires 300_CS.

Hereinafter, for convenience of descriptions, a unique identification signal for chip selection is described with reference to FIG. 4 and Table 1 below based on the case where the stack structure 200S includes four semiconductor chips 200. However, the number of semiconductor chips 200 of the stack structure 200S is not limited to four.

The semiconductor chips 200 may include the first semiconductor chip 201, the second semiconductor chip 202, a third semiconductor chip 203, and a fourth semiconductor chip 204. The first semiconductor chip 201 may be at the bottom of the stack structure 200S, the second semiconductor chip 202 may be on the first semiconductor chip 201, the third semiconductor chip 203 may be on the second semiconductor chip 202, and the fourth semiconductor chip 204 may be on the third semiconductor chip 203. In other words, the first semiconductor chip 201, the second semiconductor chip 202, the third semiconductor chip 203, and the fourth semiconductor chip 204 may be sequentially stacked.

The chip selection substrate pads 100P_CS of the package substrate 100 may include a first chip selection substrate pad 100P_CS1, a second chip selection substrate pad 100P_CS2, and a third chip selection substrate pad 100P_CS3, which are spaced apart from each other in the second horizontal direction D2.

The chip selection pads 200P_CS of the semiconductor chips 200 may include a first chip selection pad group 200P_CS1, a second chip selection pad group 200P_CS2, and a third chip selection pad group 200P_CS3. Each of the first chip selection pad group 200P_CS1, the second chip selection pad group 200P_CS2, and the third chip selection pad group 200P_CS3 may include one of a plurality of chip selection pads 201P_CS of the first semiconductor chip 201, one of a plurality of chip selection pads 202P_CS of the second semiconductor chip 202, one of a plurality of chip selection pads 203P_CS of the third semiconductor chip 203, and one of a plurality of chip selection pads 204P_CS of the fourth semiconductor chip 204.

Chip selection pads in the first chip selection pad group 200P_CS1 may be spaced apart from the first chip selection substrate pad 100P_CS1 in the first horizontal direction D1. Chip selection pads in the second chip selection pad group 200P_CS2 may be spaced apart from the second chip selection substrate pad 100P_CS2 in the first horizontal direction D1. Chip selection pads in the third chip selection pad group 200P_CS3 may be spaced apart from the third chip selection substrate pad 100P_CS3 in the first horizontal direction D1.

The chip selection wires 300_CS may include a first chip selection wire 300_CS1, a second chip selection wire 300_CS2, and a third chip selection wire 300_CS3. The first chip selection wire 300_CS1 may electrically connect the first chip selection substrate pad 100P_CS1 to the first chip selection pad group 200P_CS1. The second chip selection wire 300_CS2 may electrically connect the second chip selection substrate pad 100P_CS2 to the second chip selection pad group 200P_CS2. The third chip selection wire 300_CS3 may electrically connect the third chip selection substrate pad 100P_CS3 to the third chip selection pad group 200P_CS3.

An end of the first chip selection wire 300_CS1 may be on the top surface of the first semiconductor chip 201 and electrically connected to a chip selection pad, which is included in the first chip selection pad group 200P_CS1 among the chip selection pads 201P_CS of the first semiconductor chip 201. For example, of the chip selection pads included in the first chip selection pad group 200P_CS1, the end of the first chip selection wire 300_CS1 may contact the chip selection pad 201P_CS provided on the top surface of the first semiconductor chip 201.

An end of the second chip selection wire 300_CS2 may be on the top surface of the second semiconductor chip 202 and electrically connected to a chip selection pad, which is included in the second chip selection pad group 200P_CS2 among the chip selection pads 201P_CS of the first semiconductor chip 201 and the chip selection pads 202P_CS of the second semiconductor chip 202. For example, of the chip selection pads included in the second chip selection pad group 200P_CS2, the end of the second chip selection wire 300_CS2 may contact the chip selection pad 202P_CS provided on the top surface of the second semiconductor chip 202.

An end of the third chip selection wire 300_CS3 may be on the top surface of the third semiconductor chip 203 and electrically connected to a chip selection pad, which is included in the third chip selection pad group 200P_CS3 among the chip selection pads 201P_CS of the first semiconductor chip 201, the chip selection pads 202P_CS of the second semiconductor chip 202, and the chip selection pads 203P_CS of the third semiconductor chip 203. For example, of the chip selection pads included in the third chip selection pad group 200P_CS3, the end of the third chip selection wire 300_CS3 may contact the chip selection pad 203P_CS provided on the top surface of the third semiconductor chip 203.

A plurality of chip selection pads 201P_CS of the first semiconductor chip 201 may be respectively and electrically connected to the first chip selection wire 300_CS1, the second chip selection wire 300_CS2, and the third chip selection wire 300_CS3. For example, each of the first chip selection wire 300_CS1, the second chip selection wire 300_CS2, and the third chip selection wire 300_CS3 may contact one of the chip selection pads 201P_CS of the first semiconductor chip 201. A plurality of chip selection pads 202P_CS of the second semiconductor chip 202 may be respectively and electrically connected to the second chip selection wire 300_CS2 and the third chip selection wire 300_CS3. For example, each of the second chip selection wire 300_CS2 and the third chip selection wire 300_CS3 may contact one of the chip selection pads 202P_CS of the second semiconductor chip 202. A chip selection pad 203P_CS of the third semiconductor chip 203 may be electrically connected to the third chip selection wire 300_CS3. For example, the third chip selection wire 300_CS3 may contact one of the chip selection pads 203P_CS of the third semiconductor chip 203. The chip selection pads 204P_CS of the fourth semiconductor chip 204 may be electrically connected to none of the chip selection wires 300_CS.

TABLE 1

| | | | |
|---|---|---|---|
| Chip 4 | 0 | 0 | 0 |
| Chip 3 | 0 | 0 | 1 |
| Chip 2 | 0 | 1 | 1 |
| Chip 1 | 1 | 1 | 1 |
| | Pad 1 | Pad 2 | Pad 3 |

In Table 1, Chip 1 denotes the first semiconductor chip 201, Chip 2 denotes the second semiconductor chip 202, Chip 3 denotes the third semiconductor chip 203, and Chip 4 denotes the fourth semiconductor chip 204. Pad 1 denotes a chip selection pad 200P_CS in the first chip selection pad group 200P_CS1, Pad 2 denotes a chip selection pad 200P_CS in the second chip selection pad group 200P_CS2, and Pad 3 denotes a chip selection pad 200P_CS in the third chip selection pad group 200P_CS3.

Table 1 shows signal levels of the chip selection pads 201P_CS, 202P_CS, 203P_CS, and 204P_CS of the first to fourth semiconductor chips 201, 202, 203, and 204. The combination of respective signal levels of three chip selection pads of each of the first to fourth semiconductor chips 201, 202, 203, and 204 may form the unique identification signal of each of the first to fourth semiconductor chips 201, 202, 203, and 204.

Referring to Table 1, the unique identification signal of the first semiconductor chip 201 is [111], the unique identification signal of the second semiconductor chip 202 is [011], the unique identification signal of the third semiconductor chip 203 is [001], and the unique identification signal of the fourth semiconductor chip 204 is [000].

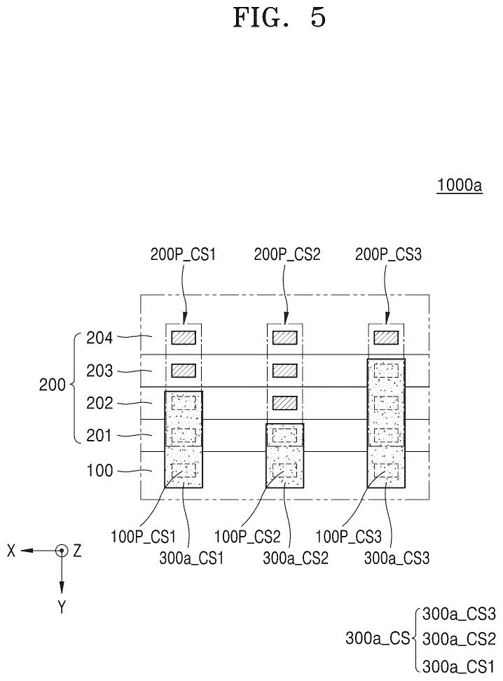

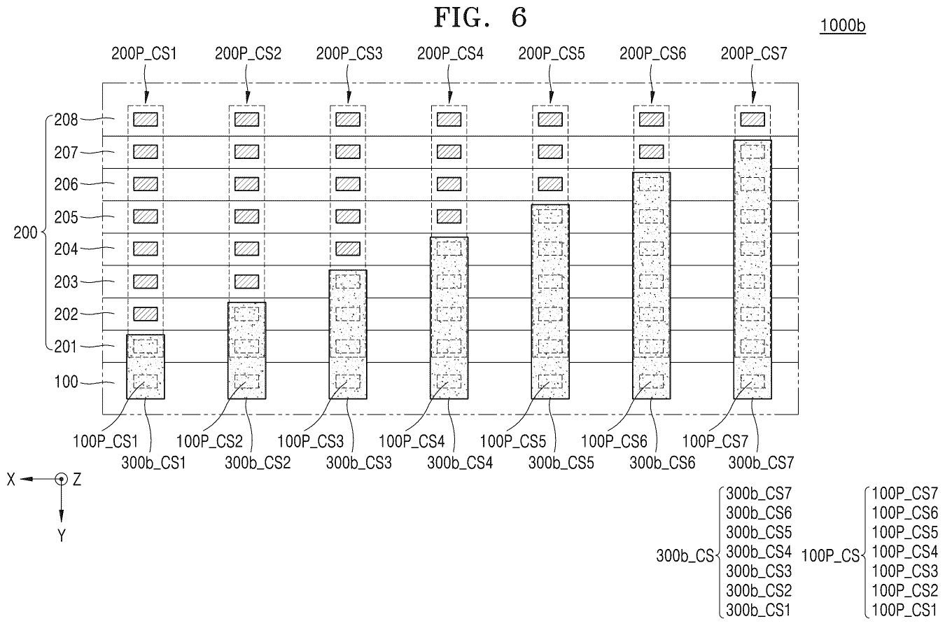

FIG. 5 is a schematic enlarged plan view of a chip selection pad portion of a semiconductor package 1000a, according to an example embodiment. FIG. 6 is a schematic enlarged plan view of a chip selection pad portion of a semiconductor package 1000b, according to an example embodiment.

The semiconductor package 1000a of FIG. 5 and the semiconductor package 1000 of FIG. 4 may differ in the unique identification signal of each of the semiconductor chips 200. The semiconductor package 1000b of FIG. 6 and the semiconductor package 1000 of FIG. 4 may differ in the number of semiconductor chips 200 and in the unique identification signal of each of the semiconductor chips 200. Redundant descriptions of the semiconductor package 1000 of FIG. 4 are omitted, and the semiconductor package 1000a of FIG. 5 and the semiconductor package 1000b of FIG. 6 are described below, focusing on the differences from the semiconductor package 1000 of FIG. 4.

The unique identification signal of each of the semiconductor chips 200 and a plurality of chip selection wires 300a_CS are described with reference to FIG. 5 and Table 2 below.

TABLE 2

| | | | |
|---|---|---|---|
| Chip 4 | 0 | 0 | 0 |
| Chip 3 | 0 | 0 | 1 |
| Chip 2 | 1 | 0 | 1 |
| Chip 1 | 1 | 1 | 1 |
| | Pad 1 | Pad 2 | Pad 3 |

The chip selection wires 300a_CS may include a first chip selection wire 300a_CS1, a second chip selection wire 300a_CS2, and a third chip selection wire 300a_CS3. The first chip selection wire 300a_CS1 may electrically connect the first chip selection substrate pad 100P_CS1 to the first chip selection pad group 200P_CS1. The second chip selection wire 300a_CS2 may electrically connect the second chip selection substrate pad 100P_CS2 to the second chip selection pad group 200P_CS2. The third chip selection wire 300a_CS3 may electrically connect the third chip selection substrate pad 100P_CS3 to the third chip selection pad group 200P_CS3.

An end of the first chip selection wire 300a_CS1 may be on the top surface of the second semiconductor chip 202 and electrically connected to a chip selection pad, which is included in the first chip selection pad group 200P_CS1 among a plurality of chip selection pads of the first semiconductor chip 201 and the second semiconductor chip 202. For example, of the chip selection pads included in the first chip selection pad group 200P_CS1, the end of the first chip selection wire 300a_CS1 may contact the chip selection pad 202P_CS provided on the top surface of the second semiconductor chip 202.

An end of the second chip selection wire 300a_CS2 may be on the top surface of the first semiconductor chip 201 and electrically connected to a chip selection pad, which is included in the second chip selection pad group 200P_CS2 among a plurality of chip selection pads of the first semiconductor chip 201. For example, of the chip selection pads included in the second chip selection pad group 200P_CS2, the end of the second chip selection wire 300a_CS2 may contact the chip selection pad 201P_CS provided on the top surface of the first semiconductor chip 201.

An end of the third chip selection wire 300a_CS3 may be on the top surface of the third semiconductor chip 203 and electrically connected to a chip selection pad, which is included in the third chip selection pad group 200P_CS3 among a plurality of chip selection pads of the first semiconductor chip 201, the second semiconductor chip 202, and the third semiconductor chip 203. For example, of the chip selection pads included in the third chip selection pad group 200P_CS3, the end of the third chip selection wire 300a_CS3 may contact the chip selection pad 203P_CS provided on the top surface of the third semiconductor chip 203.

A plurality of chip selection pads of the first semiconductor chip 201 may be respectively and electrically connected to the first chip selection wire 300a_CS1, the second chip selection wire 300a_CS2, and the third chip selection wire 300a_CS3. For example, each of the first chip selection wire 300a_CS1, the second chip selection wire 300a_CS2, and the third chip selection wire 300a_CS3 may contact one of the chip selection pads of the first semiconductor chip 201. A plurality of chip selection pads of the second semiconductor chip 202 may be respectively and electrically connected to the first chip selection wire 300a_CS1 and the third chip selection wire 300a_CS3. For example, each of the first chip selection wire 300a_CS1 and the third chip selection wire 300a_CS3 may contact one of the chip selection pads of the second semiconductor chip 202. A chip selection pad of the third semiconductor chip 203 may be electrically connected to the third chip selection wire 300a_CS3. For example, the third chip selection wire 300a_CS3 may contact one of the chip selection pads of the third semiconductor chip 203. A plurality of chip selection pads of the fourth semiconductor chip 204 may be electrically connected to none of the chip selection wires 300a_CS.

Referring to Table 2, the unique identification signal of the first semiconductor chip 201 is [111], the unique identification signal of the second semiconductor chip 202 is [101], the unique identification signal of the third semiconductor chip 203 is [001], and the unique identification signal of the fourth semiconductor chip 204 is [000].

However, the unique identification signals of the semiconductor chips 200 are not limited thereto and may be changed according to which of the first to third semiconductor chips 201, 202, and 203 an end of each of the chip selection wires 300a_CS is located.

The unique identification signal of each of the semiconductor chips 200 and a plurality of chip selection wires 300b_CS are described with reference to FIG. 6 and Table 3 below.

TABLE 3

| | | | | | | | |
|---|---|---|---|---|---|---|---|
| Chip 8 | 0 | 0 | 0 | 0 | 0 | 0 | 0 |
| Chip 7 | 0 | 0 | 0 | 0 | 0 | 0 | 1 |
| Chip 6 | 0 | 0 | 0 | 0 | 0 | 1 | 1 |
| Chip 5 | 0 | 0 | 0 | 0 | 1 | 1 | 1 |
| Chip 4 | 0 | 0 | 0 | 1 | 1 | 1 | 1 |
| Chip 3 | 0 | 0 | 1 | 1 | 1 | 1 | 1 |
| Chip 2 | 0 | 1 | 1 | 1 | 1 | 1 | 1 |
| Chip 1 | 1 | 1 | 1 | 1 | 1 | 1 | 1 |
| | Pad 1 | Pad 2 | Pad 3 | Pad 4 | Pad 5 | Pad 6 | Pad 7 |

The semiconductor chips 200 may include first to eighth semiconductor chips 201, 202, 203, 204, 205, 206, 207, and 208. The first to eighth semiconductor chips 201, 202, 203, 204, 205, 206, 207, and 208 may be sequentially stacked. For example, the first semiconductor chip 201 may be at the bottom among the semiconductor chips 200 and the eighth semiconductor chip 208 may be at the top among the semiconductor chips 200.

A plurality of chip selection substrate pads 100P_CS of the package substrate 100 may include first to seventh chip selection substrate pads 100P_CS1, 100P_CS2, 100P_CS3, 100P_CS4, 100P_CS5, 100P_CS6, and 100P_CS7, which are spaced apart from each other in the second horizontal direction D2 (in FIG. 1).

A plurality of chip selection pads 200P_CS of the semiconductor chips 200 may be divided into first to seventh chip selection pad groups 200P_CS1, 200P_CS2, 200P_CS3, 200P_CS4, 200P_CS5, 200P_CS6, and 200P_CS7.

Each of the first to seventh chip selection pad groups 200P_CS1, 200P_CS2, 200P_CS3, 200P_CS4, 200P_CS5, 200P_CS6, and 200P_CS7 may include one of the chip selection pads of each of the first to eighth semiconductor chips 201, 202, 203, 204, 205, 206, 207, and 208. In other words, each of the first to seventh chip selection pad groups 200P_CS1, 200P_CS2, 200P_CS3, 200P_CS4, 200P_CS5, 200P_CS6, and 200P_CS7 may include eight chip selection pads.

The first to seventh chip selection pad groups 200P_CS1, 200P_CS2, 200P_CS3, 200P_CS4, 200P_CS5, 200P_CS6, and 200P_CS7 may be respectively spaced apart from the first to seventh chip selection substrate pads 100P_CS1, 100P_CS2, 100P_CS3, 100P_CS4, 100P_CS5, 100P_CS6, and 100P_CS7 in the first horizontal direction D1 (in FIG. 1). For example, a chip selection pad in the first chip selection pad group 200P_CS1 may be spaced apart from the first chip selection substrate pad 100P_CS1 in the first horizontal direction D1 (in FIG. 1).

The chip selection wires 300b_CS may include first to seventh chip selection wires 300b_CS1, 300b_CS2, 300b_CS3, 300b_CS4, 300b_CS5, 300b_CS6, and 300b_CS7. The first to seventh chip selection wires 300b_CS1, 300b_CS2, 300b_CS3, 300b_CS4, 300b_CS5, 300b_CS6, and 300b_CS7 may respectively and electrically connect the first to seventh chip selection substrate pads 100P_CS1, 100P_CS2, 100P_CS3, 100P_CS4, 100P_CS5, 100P_CS6, and 100P_CS7 to the first to seventh chip selection pad groups 200P_CS1, 200P_CS2, 200P_CS3, 200P_CS4, 200P_CS5, 200P_CS6, and 200P_CS7. For example, the first chip selection wire 300b_CS1 may electrically connect the first chip selection substrate pad 100P_CS1 to the first chip selection pad group 200P_CS1.

For example, there may be eight semiconductor chips 200, seven chip selection substrate pads 100P_CS, seven chip selection pad groups, and seven chip selection wire 300b_CS. For example, when the number of semiconductor chips 200 of the stack structure 200S is N (where N is a natural number of at least 2), the number of chip selection substrate pads 100P_CS may be N−1, the number of chip selection pads 200P_CS included in each of the semiconductor chips 200 may be N−1, the number of chip selection pad groups may be N−1, and the number of chip selection wires 300_CS may be N−1.

An end of the first chip selection wire 300b_CS1 may be on the top surface of the first semiconductor chip 201 and electrically connected to a chip selection pad, which is included in the first chip selection pad group 200P_CS1 among the chip selection pads of the first semiconductor chip 201. For example, of the chip selection pads included in the first chip selection pad group 200P_CS1, the end of the first chip selection wire 300b_CS1 may contact the chip selection pad provided on the top surface of the first semiconductor chip 201.

An end of the second chip selection wire 300b_CS2 may be on the top surface of the second semiconductor chip 202 and electrically connected to a chip selection pad, which is included in the second chip selection pad group 200P_CS2 among the chip selection pads of the first semiconductor chip 201 and the second semiconductor chip 202. For example, of the chip selection pads included in the second chip selection pad group 200P_CS2, the end of the second chip selection wire 300b_CS2 may contact the chip selection pad provided on the top surface of the second semiconductor chip 202.

An end of the third chip selection wire 300b_CS3 may be on the top surface of the third semiconductor chip 203 and electrically connected to a chip selection pad, which is included in the third chip selection pad group 200P_CS3 among the chip selection pads of the first to third semiconductor chips 201, 202, and 203. For example, of the chip selection pads included in the third chip selection pad group 200P_CS3, the end of the third chip selection wire 300b_CS3 may contact the chip selection pad provided on the top surface of the third semiconductor chip 203.

An end of the fourth chip selection wire 300b_CS4 may be on the top surface of the fourth semiconductor chip 204 and electrically connected to a chip selection pad, which is included in the fourth chip selection pad group 200P_CS4 among the chip selection pads of the first to fourth semiconductor chips 201, 202, 203, and 204. For example, of the chip selection pads included in the fourth chip selection pad group 200P_CS4, the end of the fourth chip selection wire 300b_CS4 may contact the chip selection pad provided on the top surface of the fourth semiconductor chip 204.

An end of the fifth chip selection wire 300b_CS5 may be on the top surface of the fifth semiconductor chip 205 and electrically connected to a chip selection pad, which is included in the fifth chip selection pad group 200P_CS5 among the chip selection pads of the first to fifth semiconductor chips 201, 202, 203, 204, and 205. For example, of the chip selection pads included in the fifth chip selection pad group 200P_CS5, the end of the fifth chip selection wire 300b_CS5 may contact the chip selection pad provided on the top surface of the fifth semiconductor chip 205.

An end of the sixth chip selection wire 300b_CS6 may be on the top surface of the sixth semiconductor chip 206 and electrically connected to a chip selection pad, which is included in the sixth chip selection pad group 200P_CS6 among the chip selection pads of the first to sixth semiconductor chips 201, 202, 203, 204, 205, and 206. For example, of the chip selection pads included in the sixth chip selection pad group 200P_CS6, the end of the sixth chip selection wire 300b_CS6 may contact the chip selection pad provided on the top surface of the sixth semiconductor chip 206.

An end of the seventh chip selection wire 300b_CS7 may be on the top surface of the seventh semiconductor chip 207 and electrically connected to a chip selection pad, which is included in the seventh chip selection pad group 200P_CS7 among the chip selection pads of the first to seventh semiconductor chips 201, 202, 203, 204, 205, 206, and 207. For example, of the chip selection pads included in the seventh chip selection pad group 200P_CS7, the end of the seventh chip selection wire 300b_CS7 may contact the chip selection pad provided on the top surface of the seventh semiconductor chip 207.

A plurality of chip selection pads of the first semiconductor chip 201 may be respectively and electrically connected to the first to seventh chip selection wires 300b_CS1, 300b_CS2, 300b_CS3, 300b_CS4, 300b_CS5, 300b_CS6, and 300b_CS7. For example, each of the first to seventh chip selection wires 300b_CS1, 300b_CS2, 300b_CS3, 300b_CS4, 300b_CS5, 300b_CS6, and 300b_CS7 may contact one of the chip selection pads of the first semiconductor chip 201.

A plurality of chip selection pads of the second semiconductor chip 202 may be respectively and electrically connected to the second to seventh chip selection wires 300b_CS2, 300b_CS3, 300b_CS4, 300b_CS5, 300b_CS6, and 300b_CS7. For example, each of the second to seventh chip selection wires 300b_CS2, 300b_CS3, 300b_CS4, 300b_CS5, 300b_CS6, and 300b_CS7 may contact one of the chip selection pads of the second semiconductor chip 202.

A plurality of chip selection pads of the third semiconductor chip 203 may be respectively and electrically connected to the third to seventh chip selection wires 300b_CS3, 300b_CS4, 300b_CS5, 300b_CS6, and 300b_CS7. For example, each of the third to seventh chip selection wires 300b_CS3, 300b_CS4, 300b_CS5, 300b_CS6, and 300b_CS7 may contact one of the chip selection pads of the third semiconductor chip 203.

A plurality of chip selection pads of the fourth semiconductor chip 204 may be respectively and electrically connected to the fourth to seventh chip selection wires 300b_CS4, 300b_CS5, 300b_CS6, and 300b_CS7. For example, each of the fourth to seventh chip selection wires 300b_CS4, 300b_CS5, 300b_CS6, and 300b_CS7 may contact one of the chip selection pads of the fourth semiconductor chip 204.

A plurality of chip selection pads of the fifth semiconductor chip 205 may be respectively and electrically connected to the fifth to seventh chip selection wires 300b_CS5, 300b_CS6, and 300b_CS7. For example, each of the fifth to seventh chip selection wires 300b_CS5, 300b_CS6, and 300b_CS7 may contact one of the chip selection pads of the fifth semiconductor chip 205.

A plurality of chip selection pads of the sixth semiconductor chip 206 may be respectively and electrically connected to the sixth and seventh chip selection wires 300b_CS6 and 300b_CS7. For example, each of the sixth and seventh chip selection wires 300b_CS6 and 300b_CS7 may contact one of the chip selection pads of the sixth semiconductor chip 206.

A chip selection pad of the seventh semiconductor chip 207 may be electrically connected to the seventh chip selection wire 300b_CS7. For example, the seventh chip selection wire 300b_CS7 may contact one of the chip selection pads of the seventh semiconductor chip 207.

The chip selection pads of the eighth semiconductor chip 208 may not be electrically connected to any chip selection wire.

In Table 3, Chip denotes a semiconductor chip. For example, Chip 1 denotes the first semiconductor chip 201 and Chip 8 denotes the eighth semiconductor chip 208. Pad denotes a chip selection pad included in a chip selection group. For example, Pad 1 denotes a chip selection pad in the first chip selection pad group 200P_CS1 and Pad 8 denotes a chip selection pad in the eighth chip selection pad group 200P_CS8.

Table 3 shows signal levels of the chip selection pads of the first to eighth semiconductor chips 201, 202, 203, 204, 205, 206, 207, and 208. The combination of respective signal levels of seven chip selection pads of each of the first to eighth semiconductor chips 201, 202, 203, 204, 205, 206, 207, and 208 may form the unique identification signal of each of the first to eighth semiconductor chips 201, 202, 203, 204, 205, 206, 207, and 208.

Referring to Table 3, the unique identification signal of the first semiconductor chip 201 is [1111111], the unique identification signal of the second semiconductor chip 202 is [0111111], the unique identification signal of the third semiconductor chip 203 is [0011111], the unique identification signal of the fourth semiconductor chip 204 is [0001111], the unique identification signal of the fifth semiconductor chip 205 is [0000111], the unique identification signal of the sixth semiconductor chip 206 is [0000011], the unique identification signal of the seventh semiconductor chip 207 is [0000001], and the unique identification signal of the eighth semiconductor chip 208 is [0000000].

However, the unique identification signals of the semiconductor chips 200 are not limited thereto and may be changed according to which of the first to seventh semiconductor chips 201, 202, 203, 204, 205, 206, and 207 an end of each of the chip selection wires 300b_CS is located.

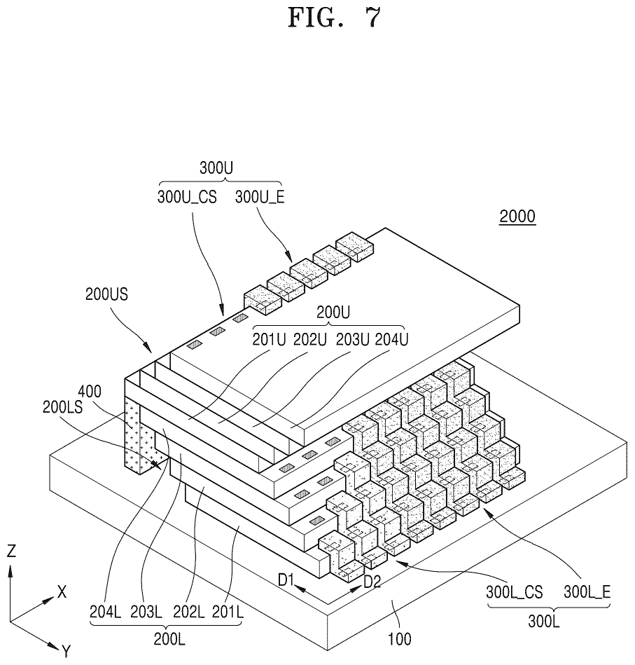

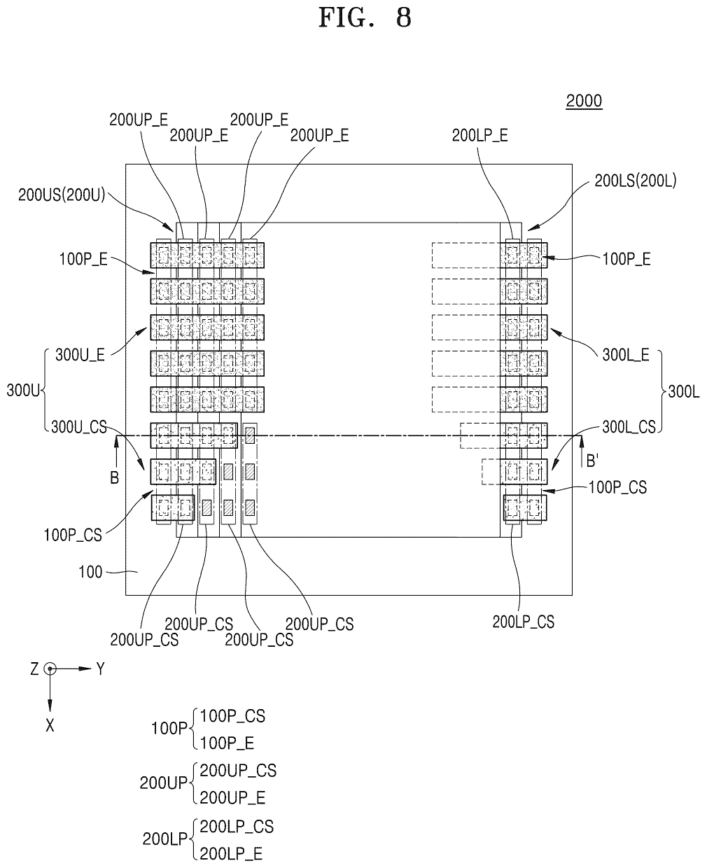

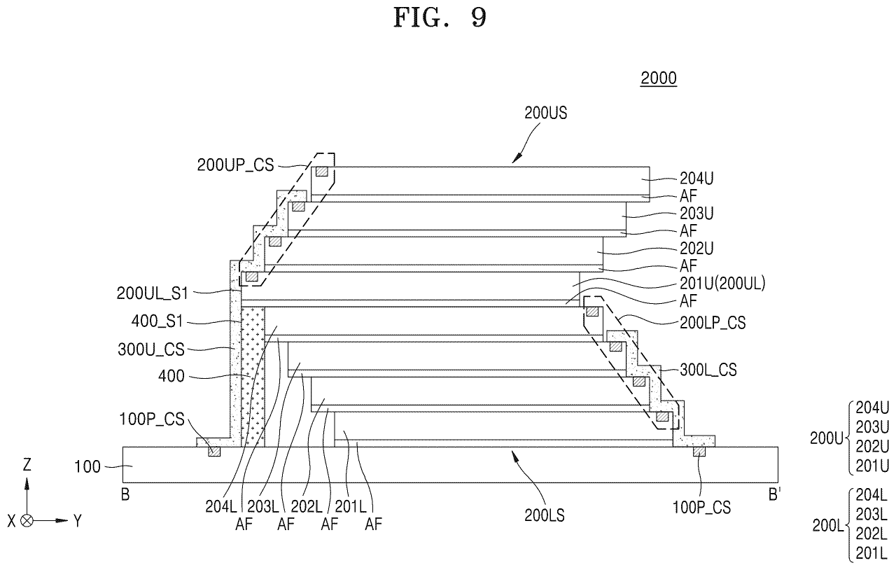

FIG. 7 is a schematic perspective view of a semiconductor package 2000 according to an example embodiment. FIG. 8 is a schematic plan view of the semiconductor package 2000 of FIG. 7. FIG. 9 is a schematic cross-sectional view of the semiconductor package 2000 of FIG. 8, taken along line B-B′ in FIG. 8.

The elements of the semiconductor package 2000 and the materials of the elements described below are mostly and substantially the same as those described above with reference to FIG. 1. For convenience of descriptions, the semiconductor package 2000 of FIG. 7 is described below, focusing on the differences from the semiconductor package 1000 of FIG. 1. Redundant descriptions will not be repeated.

The semiconductor package 2000 may include the package substrate 100, a lower stack structure 200LS, an upper stack structure 200US, a support chip 400, a plurality of lower wires 300L, and a plurality of upper wires 300U.

The lower stack structure 200LS may include lower semiconductor chips 200L, which are stacked with an offset from each other in the first horizontal direction D1. The upper stack structure 200US may include upper semiconductor chips 200U, which are stacked with an offset in a direction opposite to the first horizontal direction D1. For example, the lower stack structure 200LS may be substantially the same as the stack structure 200S in FIG. 1. The upper stack structure 200US may be substantially the same as the stack structure 200S in FIG. 1, except for the offset direction.

The lower stack structure 200LS may be on the package substrate 100 and the upper stack structure 200US may be on the lower stack structure 200LS. The upper stack structure 200US may be stacked on the lower stack structure 200LS with an offset in the first horizontal direction D1. For example, a bottommost upper semiconductor chip of the upper stack structure 200US may be stacked on a topmost lower semiconductor chip 200L of the lower stack structure 200LS with an offset in the first horizontal direction D1.

In some embodiments, the lower semiconductor chips 200L may include first to fourth lower semiconductor chips 201L, 202L, 203L, and 204L. The first to fourth lower semiconductor chips 201L, 202L, 203L, and 204L may be stacked sequentially offset in the first horizontal direction D1. For example, the first lower semiconductor chip 201L may be on the package substrate 100.

In some embodiments, the upper semiconductor chips 200U may include first to fourth upper semiconductor chips 201U, 202U, 203U, and 204U. The first to fourth upper semiconductor chips 201U, 202U, 203U, and 204U may be stacked sequentially offset in the direction opposite to the first horizontal direction D1. For example, the first upper semiconductor chip 201U may be on the fourth lower semiconductor chip 204L. The first upper semiconductor chip 201U may be referred to as a bottommost first upper semiconductor chip 200UL among the upper semiconductor chips 200U.

Each of the lower semiconductor chips 200L may include a plurality of lower chip pads 200LP. The lower chip pads 200LP may include a plurality of lower chip selection pads 200LP_CS and a lower chip signal pad 200LP_E. Each of the upper semiconductor chips 200U may include a plurality of upper chip pads 200UP. The upper chip pads 200UP may include a plurality of upper chip selection pads 200UP_CS and an upper chip signal pad 200UP_E.

In some embodiments, the number of lower chip selection pads 200LP_CS of each of the lower semiconductor chips 200L may be less than the number of lower semiconductor chips 200L. The number of upper chip selection pads 200UP_CS of each of the upper semiconductor chips 200U may be less than the number of upper semiconductor chips 200U. For example, when the number of lower semiconductor chips 200L is N, the number of lower chip selection pads 200LP_CS included in each of the lower semiconductor chips 200L may be N−1. When the number of upper semiconductor chips 200U is N, the number of upper chip selection pads 200UP_CS included in each of the upper semiconductor chips 200U may be N−1.

In some embodiments, the lower chip pads 200LP may be on the top surface of each of the lower semiconductor chips 200L. In example embodiments, top surfaces of each of the lower chip pads 200LP may be coplanar with top surfaces of the lower semiconductor chips 200L on which the lower chip pads 200LP are provided. The lower chip pads 200LP may be arranged on the top surface of each of the lower semiconductor chips 200L along a first side surface of each of the lower semiconductor chips 200L. The upper chip pads 200UP may be on the top surface of each of the upper semiconductor chips 200U. In example embodiments, top surfaces of each of the upper chip pads 200UP may be coplanar with top surfaces of the upper semiconductor chips 200U on which the upper chip pads 200UP are provided. The upper chip pads 200UP may be arranged on the top surface of each of the upper semiconductor chips 200U along a first side surface of each of the upper semiconductor chips 200U.

In some embodiments, the first side surface of each of the lower semiconductor chips 200L may be spaced apart from the first side surface of each of the upper semiconductor chips 200U in the first horizontal direction D1. For example, the distance between the first side surface of each of the lower semiconductor chips 200L and the first side surface of each of the upper semiconductor chips 200U may be greater than the offset between the upper stack structure 200US and the lower stack structure 200LS. A first side surface 200UL_S1 of the bottommost first upper semiconductor chip 200UL may not overlap the lower stack structure 200LS in the vertical direction (the Z direction).

The support chip 400 may be on the package substrate 100. The support chip 400 may be in contact with the bottom surface of the upper stack structure 200US. For example, the support chip 400 may be in contact with the bottom surface of a portion of the upper stack structure 200US, which protrudes outwards from the lower stack structure 200LS. For example, the support chip 400 may contact a lower surface of the adhesive member AF disposed below the bottommost first upper semiconductor chip 200UL and the top surface of the package substrate 100. In some embodiments, the height of the support chip 400 may be the same as the height of the lower stack structure 200LS. For example, a top surface of the support chip 400 may be coplanar with a top surface of the topmost lower semiconductor chip 200L of the lower stack structure 200LS. The support chip 400 may support a lower portion of the upper stack structure 200US, thereby increasing the mechanical stability of the semiconductor package 2000.

In some embodiments, a side surface of the upper stack structure 200US may be coplanar with a side surface of the support chip 400. The first side surface 200UL_S1 of the bottommost first upper semiconductor chip 200UL may be coplanar with a first side surface 400_S1 of the support chip 400. For example, the top surface of the support chip 400 may be in contact with the upper stack structure 200US, and a side surface of the support chip 400, which is opposite to the first side surface 400_S1 of the support chip 400, may be in contact with the lower stack structure 200LS. For example, the support chip 400 may contact a side surface of the topmost lower semiconductor chip 200L of the lower stack structure 200LS.

The lower wires 300L may include a lower signal wire 300L_E and a plurality of lower chip selection wires 300L_CS. The upper wires 300U may include an upper signal wire 300U_E and a plurality of upper chip selection wires 300U_CS.

The lower chip selection wires 300L_CS may electrically connect the package substrate 100 to the lower stack structure 200LS. The upper chip selection wires 300U_CS may electrically connect the package substrate 100 to the upper stack structure 200US.

Each of the lower chip selection wires 300L_CS may extend from the package substrate 100 to one of the lower semiconductor chips 200L along the top and side surfaces of the lower stack structure 200LS. Each of the upper chip selection wires 300U_CS may extend from the package substrate 100 to one of the upper semiconductor chips 200U along an outer surface of the support chip 400 and the top and side surfaces of the upper stack structure 200US. For example, the lower chip selection wires 300L_CS may contact the top and side surfaces of the lower stack structure 200LS, and the upper chip selection wires 300U_CS may contact the outer surface of the support chip 400 and the top and side surfaces of the upper stack structure 200US.

The lower chip selection wires 300L_CS may be substantially the same as the chip selection wires 300_CS in FIG. 2. The upper chip selection wires 300U_CS may be substantially the same as the chip selection wires 300_CS in FIG. 2, except that the upper chip selection wires 300U_CS are in contact with the outer surface of the support chip 400.

In some embodiments, the lower chip selection wires 300L_CS may extend in the first horizontal direction D1 along the top surface of the lower stack structure 200LS and in the vertical direction (the Z direction) along the side surface of the lower stack structure 200LS.

In some embodiments, the upper chip selection wires 300U_CS may extend in the direction opposite to the first horizontal direction D1 along the top surface of the upper stack structure 200US and in the vertical direction (the Z direction) along the side surface of the upper stack structure 200US and the first side surface 400_S1 of the support chip 400. For example, the upper chip selection wires 300U_CS may extend in the vertical direction (the Z direction) along the first side surface 200UL_S1 of the bottommost first upper semiconductor chip 200UL and the first side surface 400_S1 of the support chip 400.

In some embodiments, the extension length of each of the lower chip selection wires 300L_CS may be less than the extension length of the lower signal wire 300L_E. The lower chip selection wires 300L_CS may have different extension lengths. One ends of the lower chip selection wires 300L_CS may be respectively located on the top surfaces of different lower semiconductor chips among the lower semiconductor chips 200L.

In some embodiments, the extension length of each of the upper chip selection wires 300U_CS may be less than the extension length of the upper signal wire 300U_E. The upper chip selection wires 300U_CS may have different extension lengths. One ends of the upper chip selection wires 300U_CS may be respectively located on the top surfaces of different lower semiconductor chips among the upper semiconductor chips 200U.

In some embodiments, the lower chip selection wires 300L_CS may be electrically connected to different numbers of lower semiconductor chips 200L. For example, when the number of lower semiconductor chips 200L is N, each of the lower chip selection wires 300L_CS may be electrically connected to one to N−1 lower semiconductor chips 200L, and the lower chip selection wires 300L_CS may be electrically connected to different numbers of lower semiconductor chips 200L.

In some embodiments, the upper chip selection wires 300U_CS may be electrically connected to different numbers of upper semiconductor chips 200U. For example, when the number of upper semiconductor chips 200U is N, each of the upper chip selection wires 300U_CS may be electrically connected to one to N−1 upper semiconductor chips 200U, and the upper chip selection wires 300U_CS may be electrically connected to different numbers of upper semiconductor chips 200U.

In some embodiments, a lower semiconductor chip having on a top surface thereof an end of one of the lower chip selection wires 300L_CS may be referred to as a lower target semiconductor chip of one of the lower chip selection wires 300L_CS. Each of the lower chip selection wires 300L_CS may be electrically connected to a lower target semiconductor chip thereof. Each of the lower chip selection wires 300L_CS may be electrically connected to all lower semiconductor chips between the lower target semiconductor chip thereof and the package substrate 100.

In some embodiments, an upper semiconductor chip having on a top surface thereof an end of one of the upper chip selection wires 300U_CS may be referred to as an upper target semiconductor chip of one of the upper chip selection wires 300U_CS. Each of the upper chip selection wires 300U_CS may be electrically connected to an upper target semiconductor chip thereof. Each of the upper chip selection wires 300U_CS may be electrically connected to all upper semiconductor chips between the upper target semiconductor chip thereof and the package substrate 100.

The size of the semiconductor package 2000 may be reduced by stacking the upper stack structure 200US on the lower stack structure 200LS. The semiconductor package 2000 may electrically connect the upper stack structure 200US and the lower stack structure 200LS to the package substrate 100 through the upper wires 300U and the lower wires 300L, thereby shortening an electrical signal and increasing electrical reliability.

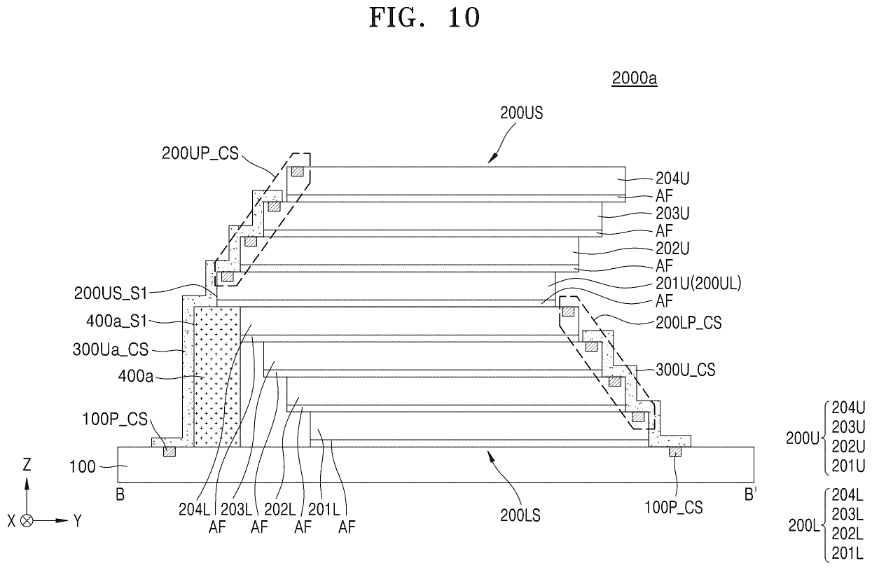

FIG. 10 is a schematic cross-sectional view of a semiconductor package 2000a, taken along line B-B′ in FIG. 8, according to an example embodiment.

The elements of the semiconductor package 2000a and the materials of the elements described below are mostly and substantially the same as those described above with reference to FIG. 9. For convenience of descriptions, the semiconductor package 2000a of FIG. 10 is described below, focusing on the differences from the semiconductor package 2000 of FIG. 9. Redundant descriptions will not be repeated.

The semiconductor package 2000a may include a support chip 400a. The support chip 400a may be on the package substrate 100. The top surface of the support chip 400a may be in contact with the bottom surface of the upper stack structure 200US. For example, the support chip 400a may be in contact with the bottom surface of a portion of the upper stack structure 200US, which protrudes outwards from the lower stack structure 200LS. For example, the support chip 400a may contact a lower surface of the adhesive member AF disposed below the bottommost first upper semiconductor chip 200UL and the top surface of the package substrate 100. In some embodiments, the height of the support chip 400a may be the same as the height of the lower stack structure 200LS. For example, a top surface of the support chip 400a may be coplanar with a top surface of the topmost lower semiconductor chip 200L of the lower stack structure 200LS. The support chip 400a may support a lower portion of the upper stack structure 200US, thereby increasing the mechanical stability of the semiconductor package 2000a.

In some embodiments, the support chip 400a may protrude outwards from the upper stack structure 200US. In other words, a portion of the top surface of the support chip 400a may be covered with the upper stack structure 200US and the other portion of the top surface of the support chip 400a may be exposed. For example, when a side surface, which is not in contact with the lower stack structure 200LS, between opposite side surfaces of the support chip 400a that are spaced apart from each other in the first horizontal direction D1 is the first side surface 400a_S1 of the support chip 400a, the whole of a first side surface 200US_S1 of the upper stack structure 200US may not be coplanar with the first side surface 400a_S1 of the support chip 400a. In other words, the first side surface 400a_S1 of the support chip 400a may not overlap the upper stack structure 200US in the vertical direction (the Z direction).

Each of a plurality of upper chip selection wires 300Ua_CS may extend from the package substrate 100 to one of the upper semiconductor chips 200U along the top and side surface of the upper stack structure 200US and an outer surface of the support chip 400a. For example, plurality of upper chip selection wires 300Ua_CS may contact the first side surface 400a_S1 and the exposed portion of the top surface of the support chip 400a.

In some embodiments, the upper chip selection wires 300Ua_CS may extend in the direction opposite to the first horizontal direction D1 along the top surface of the upper stack structure 200US and in the vertical direction (the Z direction) along the first side surface 200US_S1 of the upper stack structure 200US. The upper chip selection wires 300Ua_CS may extend in the direction opposite to the first horizontal direction D1 along the top surface of the support chip 400a and in the vertical direction (the Z direction) along the first side surface 400a_S1 of the support chip 400a.

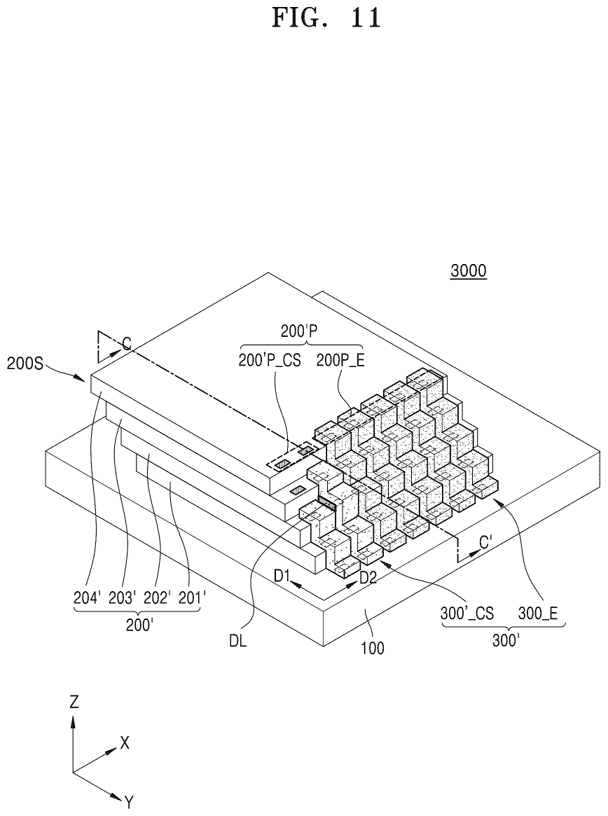

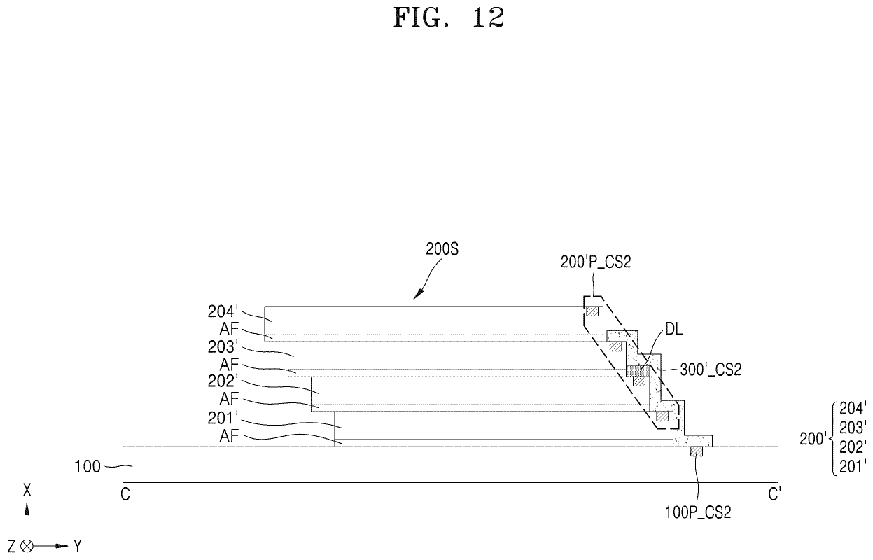

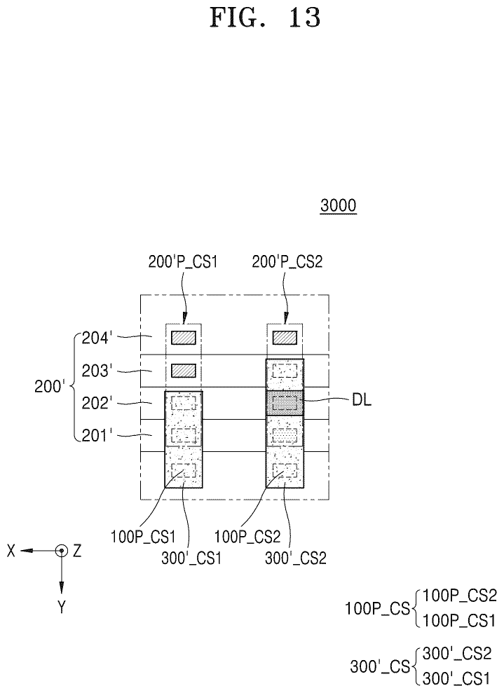

FIG. 11 is a schematic perspective view of a semiconductor package 3000 according to an example embodiment. FIG. 12 is a schematic cross-sectional view of the semiconductor package 3000 of FIG. 11, taken along line C-C′ in FIG. 11. FIG. 13 is a schematic enlarged plan view of a chip selection pad portion of the semiconductor package 3000 of FIG. 12.

The elements of the semiconductor package 3000 and the materials of the elements described below are mostly and substantially the same as those described above with reference to FIG. 1. For convenience of descriptions, the semiconductor package 3000 of FIG. 11 is described below, focusing on the differences from the semiconductor package 1000 of FIG. 1. Redundant descriptions will not be repeated.

The semiconductor package 3000 may include an insulating cover DL. The insulating cover DL may be on the top surface of the stack structure 200S. For example, the insulating cover DL may be on the top surface of one of a plurality of semiconductor chips 200′ of the stack structure 200S.

Each of the semiconductor chips 200′ may include a plurality of pads 200′P, where the plurality of pads 200′P includes a plurality of signal pads 200′P_E and a plurality of chip selection pads 200′P_CS. The insulating cover DL may cover at least one of a plurality of chip selection pads 200′P_CS of the semiconductor chips 200′. For example, the insulating cover DL may cover one of the chip selection pads 200′P_CS of one of the semiconductor chips 200′. In example embodiments, the insulating cover DL may contact at least one of the plurality of chip selection pads 200′P_CS of the semiconductor chips 200′. For example, the insulating cover DL may contact one of the chip selection pads 200′P_CS of one of the semiconductor chips 200′.

The top surface of the insulating cover DL may be in contact with at least one of a plurality of chip selection wires 300′_CS. For example, the insulating cover DL may be between the chip selection wires 300′_CS and the stack structure 200S. The insulating cover DL may insulate the chip selection wires 300′_CS from at least one of the semiconductor chips 200′ of the stack structure 200S.

In some embodiments, a vertical level of a semiconductor chip, on a top surface of which an end of a chip selection wire in contact with the insulating cover DL is located, is higher than the vertical level of the insulating cover DL. In other words, a chip selection wire in contact with the insulating cover DL among the chip selection wires 300′_CS may extend above a semiconductor chip having thereon the insulating cover DL. For example, when one of the chip selection wires 300′_CS has an end on the top surface of a target semiconductor chip thereof and is in contact with the insulating cover DL, a semiconductor chip on which the insulating cover DL is located is located lower than the target semiconductor chip.

For example, referring to FIG. 12, an end of a second chip selection wire 300′_CS2 among the chip selection wires 300′_CS may be on the top surface of a third semiconductor chip 203′. The insulating cover DL may be on the top surface of a second semiconductor chip 202′ below the third semiconductor chip 203′. The insulating cover DL may cover some of the chip selection pads 200′P_CS of the second semiconductor chip 202′. The insulating cover DL may contact some of the chip selection pads 200′P_CS of the second semiconductor chip 202′. The insulating cover DL may be between the second chip selection wire 300′_CS2 and the second semiconductor chip 202′.

The insulating cover DL may electrically insulate the second chip selection wire 300′_CS2 from the second semiconductor chip 202′. In other words, the second chip selection wire 300′_CS2 may extend from the package substrate 100 to the top surface of the third semiconductor chip 203′ and may be electrically connected to a first semiconductor chip 201′ and the third semiconductor chip 203′.

Although it is illustrated in FIG. 11 that the insulating cover DL covers one of the chip selection pads 200′P_CS of one semiconductor chip, embodiments are not limited thereto. The insulating cover DL may cover at least two of the chip selection pads 200′P_CS of one semiconductor chip. For example, the insulating cover DL may contact at least two of the chip selection pads 200′P_CS of one semiconductor chip. The insulating cover DL may also extend along the side surface of the stack structure 200S to be in contact with the top surfaces of at least two of the semiconductor chips 200′.

The stack structure 200S may include the semiconductor chips 200′. Each of the semiconductor chips 200′ may include a plurality of pads 200′P. The pads 200′P may include the chip selection pads 200′P_CS and a signal pad 200P_E. A plurality of wires 300′ may include the chip selection wires 300′_CS and a signal wire 300_E. For example, the chip selection pads 200′P_CS may electrically connect the chip selection substrate pads 100P_CS of the package substrate 100 to the chip selection pads 200′P_CS.

In some embodiments, the number of chip selection pads 200′P_CS of each of the semiconductor chips 200′ may be less than the number of semiconductor chips 200′. For example, when the number of chip selection pads 200′P_CS of each of the semiconductor chips 200′ is M (where M is a natural number of at least 2), the number of semiconductor chips 200′ may be 2M.

In some embodiments, the wires 300′ may extend in the first horizontal direction D1 along the top surface of the stack structure 200S and in the vertical direction (the Z direction) along a side surface of the stack structure 200S. The extension length of each of the chip selection wires 300′_CS may be less than the extension length of the signal wire 300_E.

In some embodiments, the extension lengths of the chip selection wires 300′_CS may be different. For example, one ends of the chip selection wires 300′_CS may be respectively on the top surfaces of different semiconductor chips among the semiconductor chips 200′, and accordingly, the extension lengths of the chip selection wires 300′_CS may be different.

In some embodiments, the chip selection wires 300′_CS may be connected to the same number of semiconductor chips 200′. For example, a semiconductor chip having on a top surface thereof an end of one of the chip selection wires 300′_CS may be referred to as a target semiconductor chip of one of the chip selection wires 300′_CS. Each of the chip selection wires 300′_CS may be electrically connected to the target semiconductor chip thereof and some of semiconductor chips 200′ between the target semiconductor chip and the package substrate 100. Accordingly, even when the respective target semiconductor chips of the chip selection wires 300′_CS are different, the chip selection wires 300′_CS may be electrically connected to the same number of semiconductor chips 200′.

The unique identification signals of the semiconductor chips 200′ are described with reference to FIG. 13 and Table 4 below.

TABLE 4

| | | |
|---|---|---|
| Chip 4 | 0 | 0 |
| Chip 3 | 0 | 1 |
| Chip 2 | 1 | 0 |
| Chip 1 | 1 | 1 |
| | Pad 1 | Pad 2 |

The semiconductor chips 200′ may include first to fourth semiconductor chips 201′, 202′, 203′, and 204′. The first to fourth semiconductor chips 201′, 202′, 203′, and 204′ may be stacked sequentially offset in the first horizontal direction D1. For example, the first semiconductor chip 201′ may be at the bottom among the semiconductor chips 200′ and the fourth semiconductor chip 204′ may be at the top among the semiconductor chips 200′.

A plurality of chip selection pads 200′P_CS of the semiconductor chips 200′ may be divided into a first chip selection pad group 200′P_CS1 and a second chip selection pad group 200′P_CS2. Each of the first chip selection pad group 200′P_CS1 and the second chip selection pad group 200′P_CS2 may include one of a plurality of chip selection pads 200′P_CS of the first semiconductor chip 201′, one of a plurality of chip selection pads 200′P_CS of the second semiconductor chip 202′, one of a plurality of chip selection pads 200′P_CS of the third semiconductor chip 203′, and one of a plurality of chip selection pads 200′P_CS of the fourth semiconductor chip 204′.

Chip selection pads in the first chip selection pad group 200′P_CS1 may be spaced apart from the first chip selection substrate pad 100P_CS1 in the first horizontal direction D1. Chip selection pads in the second chip selection pad group 200′P_CS2 may be spaced apart from the second chip selection substrate pad 100P_CS2 in the first horizontal direction D1.

The chip selection wires 300′_CS may include a first chip selection wire 300′_CS1 and a second chip selection wire 300′_CS2. The first chip selection wire 300′_CS1 may electrically connect the first chip selection substrate pad 100P_CS1 to the first chip selection pad group 200′P_CS1. The second chip selection wire 300′_CS2 may electrically connect the second chip selection substrate pad 100P_CS2 to the second chip selection pad group 200′P_CS2.

For example, an end of the first chip selection wire 300′_CS1 may be on the top surface of the second semiconductor chip 202′ and an end of the second chip selection wire 300′_CS2 may be on the top surface of the third semiconductor chip 203′. For example, of the chip selection pads included in the first chip selection pad group 200′P_CS1, the end of the first chip selection wire 300′_CS1 may contact the chip selection pad provided on the top surface of the second semiconductor chip 202′. In addition, of the chip selection pads included in the second chip selection pad group 200′P_CS2, the end of the second chip selection wire 300′_CS2 may contact the chip selection pad provided on the top surface of the third semiconductor chip 203′.

The insulating cover DL may be on the top surface of the second semiconductor chip 202′ and between the second chip selection wire 300′_CS2 and the second semiconductor chip 202′. For example, the insulating cover DL may cover a chip selection pad in the second chip selection pad group 200′P_CS2 among the plurality of chip selection pads of the second semiconductor chip 202′. For example, of the chip selection pads included in the second chip selection pad group 200′P_CS2 the insulating cover DL may contact the chip selection pad provided on the top surface of the second semiconductor chip 202′.

The first chip selection wire 300′_CS1 may be electrically connected to chip selection pads in the first chip selection pad group 200′P_CS1, which are respectively included in the first semiconductor chip 201′ and the second semiconductor chip 202′. The second chip selection wire 300′_CS2 may be electrically connected to chip selection pads in the second chip selection pad group 200′P_CS2, which are respectively included in the first semiconductor chip 201′ and the third semiconductor chip 203′. The second chip selection wire 300′_CS2 may be electrically insulated by the insulating cover DL from a chip selection pad in the second chip selection pad group 200′P_CS2, which is included in the second semiconductor chip 202′. The number of semiconductor chips electrically connected to the first chip selection wire 300′_CS1 may be the same as the number of semiconductor chips electrically connected to the second chip selection wire 300′_CS2.

The chip selection pads 200′P_CS of the first semiconductor chip 201′ may be respectively and electrically connected to the first chip selection wire 300′_CS1 and the second chip selection wire 300′_CS2. For example, each of the first chip selection wire 300′_CS1 and the second chip selection wire 300′_CS2 may contact one of the chip selection pads of the first semiconductor chip 201′. One of the chip selection pads 200′P_CS of the second semiconductor chip 202′ may be electrically connected to the first chip selection wire 300′_CS1. For example, the first chip selection wire 300′_CS1 may contact one of the chip selection pads of the second semiconductor chip 202′. One of the chip selection pads 200′P_CS of the third semiconductor chip 203′ may be electrically connected to the second chip selection wire 300′_CS2. For example, the second chip selection wire 300′_CS2 may contact one of the chip selection pads of the third semiconductor chip 203′. The chip selection pads 200′P_CS of the fourth semiconductor chip 204′ may not be electrically connected to any chip selection wire.

Referring to Table 4, the unique identification signal of the first semiconductor chip 201′ is [11], the unique identification signal of the second semiconductor chip 202′ is [10], the unique identification signal of the third semiconductor chip 203′ is [01], and the unique identification signal of the fourth semiconductor chip 204′ is [00]. However, the unique identification signal of each of the semiconductor chips 200′ is not limited thereto.

The semiconductor package 3000 may form a unique identification signal of each of the semiconductor chips 200′ by combining the signal levels of a relatively small number of chip selection pads.

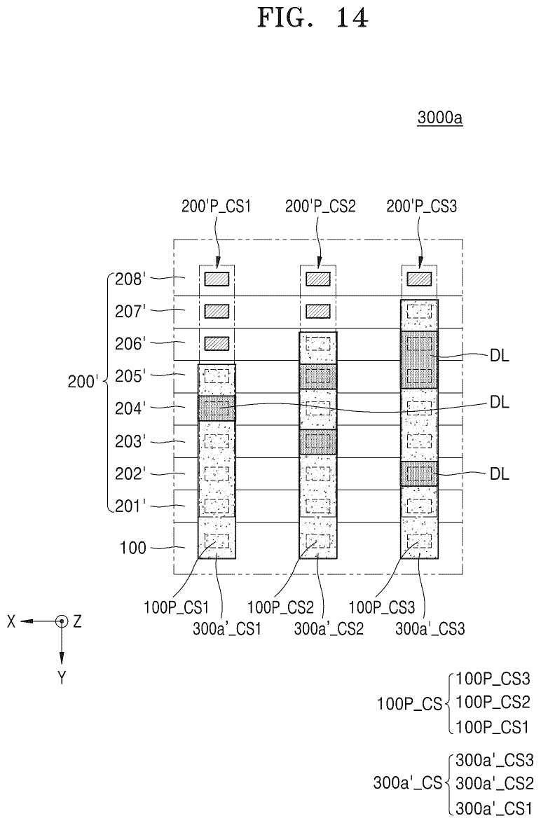

FIG. 14 is a schematic enlarged plan view of a chip selection pad portion of a semiconductor package 3000a, according to an example embodiment.

The semiconductor package 3000a of FIG. 14 and the semiconductor package 3000 of FIG. 13 differ in the number of semiconductor chips 200′. Redundant descriptions of the semiconductor package 3000a of FIG. 14 will not be repeated, and the semiconductor package 3000a of FIG. 14 is described below, focusing on the differences from the semiconductor package 3000 of FIG. 13.

The unique identification signal of each of a plurality of semiconductor chips 200′ and a plurality of chip selection wires 300a′_CS are described with reference to FIG. 14 and Table 5 below.

TABLE 5

| | | | |
|---|---|---|---|
| Chip 8 | 0 | 0 | 0 |
| Chip 7 | 0 | 0 | 1 |
| Chip 6 | 0 | 1 | 0 |
| Chip 5 | 1 | 0 | 0 |
| Chip 4 | 0 | 1 | 1 |
| Chip 3 | 1 | 0 | 1 |
| Chip 2 | 1 | 1 | 0 |
| Chip 1 | 1 | 1 | 1 |
| | Pad 1 | Pad 2 | Pad 3 |

The semiconductor chips 200′ may include first to eighth semiconductor chips 201′, 202′, 203′, 204′, 205′, 206′, 207′, and 208′. The first to eighth semiconductor chips 201′, 202′, 203′, 204′, 205′, 206′, 207′, and 208′ may be sequentially stacked. For example, the first semiconductor chip 201′ may be at the bottom among the semiconductor chips 200′ and the eighth semiconductor chip 208′ may be at the top among the semiconductor chips 200′.

A plurality of chip selection substrate pads 100P_CS of the package substrate 100 may include first to third chip selection substrate pads 100P_CS1, 100P_CS2, and 100P_CS3, which are spaced apart from each other in the second horizontal direction D2 (in FIG. 11).

A plurality of chip selection pads 200′P_CS (in FIG. 11) of the semiconductor chips 200′ may be divided into first to third chip selection pad groups 200′P_CS1, 200′P_CS2, and 200′P_CS3.

Each of the first to third chip selection pad groups 200′P_CS1, 200′P_CS2, and 200′P_CS3 may include one of a plurality of chip selection pads of each of the first to eighth semiconductor chips 201′, 202′, 203′, 204′, 205′, 206′, 207′, and 208′. In other words, each of the first to third chip selection pad groups 200′P_CS1, 200′P_CS2, and 200′P_CS3 may include eight chip selection pads.

The first to third chip selection pad groups 200′P_CS1, 200′P_CS2, and 200′P_CS3 may be spaced apart from the first to third chip selection substrate pads 100P_CS1, 100P_CS2, and 100P_CS3 in the first horizontal direction D1 (in FIG. 11). For example, chip selection pads in the first chip selection pad group 200′P_CS1 may be spaced apart from the first chip selection substrate pad 100P_CS1 in the first horizontal direction D1 (in FIG. 11).

For example, there may be eight semiconductor chips 200′, three chip selection substrate pads 100P_CS, three chip selection pad groups, and three chip selection wires 300a′_CS.

To form the unique identification signals of the semiconductor chips 200′, an insulating cover DL may be between the chip selection wires 300a′_CS and a plurality of semiconductor chips 200′. For example, the insulating cover DL may be on the top surface of the stack structure 200S (in FIG. 11) such that the signal levels of chip selection pads 200′P_CS (in FIG. 11) of the semiconductor chips 200′ are not the same.

The insulating cover DL may be between the first chip selection wire 300a′_CS1 and the stack structure 200S (in FIG. 11). In detail, the insulating cover DL may be between the first chip selection wire 300a′_CS1 and the fourth semiconductor chip 204′. Accordingly, the first chip selection wire 300a′_CS1 may be electrically connected to chip selection pads, which are respectively included in the first semiconductor chip 201′, the second semiconductor chip 202′, the third semiconductor chip 203′, and the fifth semiconductor chip 205′, among the chip selection pads in the first chip selection pad group 200′P_CS1.

The insulating cover DL may be between the second chip selection wire 300a′_CS2 and the stack structure 200S (in FIG. 11). In detail, the insulating cover DL may be between the second chip selection wire 300a′_CS2 and the third semiconductor chip 203′ and between the second chip selection wire 300a′_CS2 and the fifth semiconductor chip 205′. Accordingly, the second chip selection wire 300a′_CS2 may be electrically connected to chip selection pads, which are respectively included in the first semiconductor chip 201′, the second semiconductor chip 202′, the fourth semiconductor chip 204′, and the sixth semiconductor chip 206′, among the chip selection pads in the second chip selection pad group 200′P_CS2.

The insulating cover DL may be between the third chip selection wire 300a′_CS3 and the stack structure 200S (in FIG. 11). In detail, the insulating cover DL may be between the third chip selection wire 300a′_CS3 and the second semiconductor chip 202′, between the third chip selection wire 300a′_CS3 and the fifth semiconductor chip 205′, and between the third chip selection wire 300a′_CS3 and the sixth semiconductor chip 206′. Accordingly, the third chip selection wire 300a′_CS3 may be electrically connected to chip selection pads, which are respectively included in the first semiconductor chip 201′, the third semiconductor chip 203′, the fourth semiconductor chip 204′, and the seventh semiconductor chip 207′, among the chip selection pads in the third chip selection pad group 200′P_CS3.

Referring to Table 5, the unique identification signal of the first semiconductor chip 201′ is [111], the unique identification signal of the second semiconductor chip 202′ is [110], the unique identification signal of the third semiconductor chip 203′ is [101], the unique identification signal of the fourth semiconductor chip 204′ is [011], the unique identification signal of the fifth semiconductor chip 205′ is [100], the unique identification signal of the sixth semiconductor chip 206′ is [010], the unique identification signal of the seventh semiconductor chip 207′ is [001], and the unique identification signal of the eighth semiconductor chip 208′ is [000]. However, the unique identification signal of each semiconductor chip is not limited thereto.

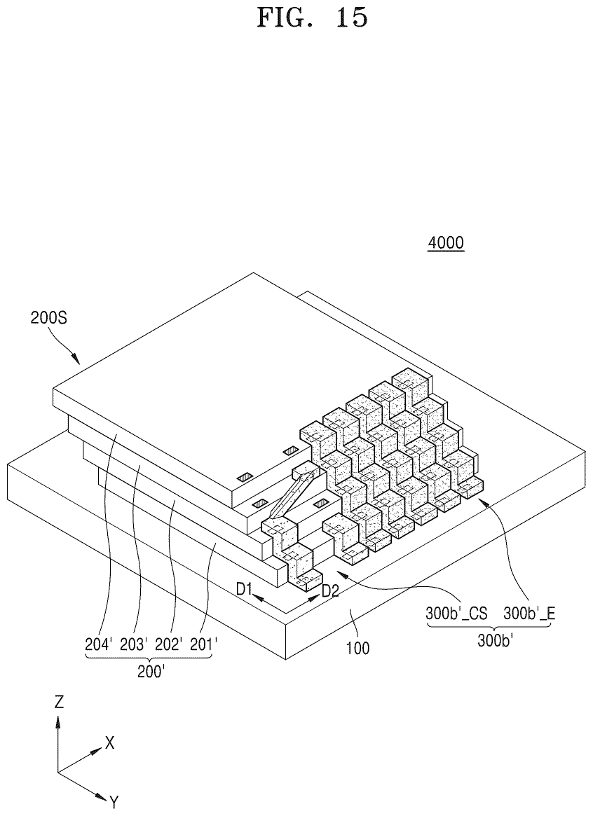

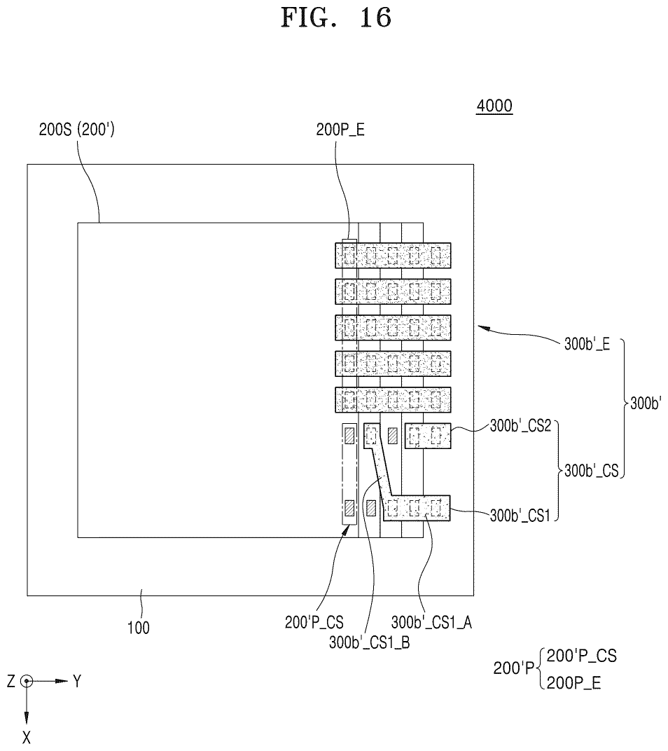

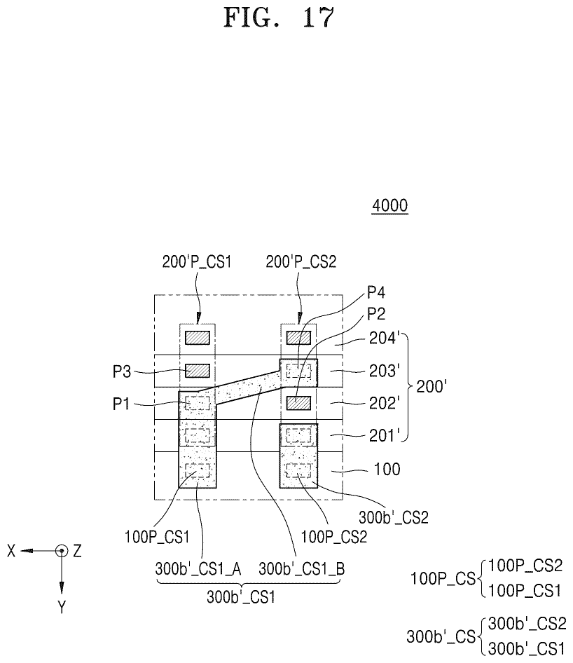

FIG. 15 is a schematic perspective view of a semiconductor package 4000 according to an example embodiment. FIG. 16 is a schematic plan view of the semiconductor package 4000 of FIG. 15. FIG. 17 is a schematic enlarged plan view of a chip selection pad portion of the semiconductor package 4000 of FIG. 16.

The elements of the semiconductor package 4000 and the materials of the elements described below are mostly and substantially the same as those described above with reference to FIG. 11. For convenience of descriptions, the semiconductor package 4000 of FIG. 15 is described below, focusing on the differences from the semiconductor package 3000 of FIG. 11. Redundant descriptions will not be repeated.

The semiconductor package 3000 may include a plurality of wires 300b′. The wires 300b′ may electrically connect the package substrate 100 to the stack structure 200S. Each of the wires 300b′ may extend from the package substrate 100 to one of a plurality of semiconductor chips 200′ of the stack structure 200S along the side and top surfaces of the stack structure 200S.

The wires 300b′ may include a plurality of chip selection wires 300b′_CS and a signal wire 300b′_E. Some of the chip selection wires 300b′_CS may include a first portion 300b′_CS1_A and a second portion 300b′_CS1_B, which extend in different directions. For example, in a plan view, some of the chip selection wires 300b′_CS may include the first portion 300b′_CS1_A, which extends in the first horizontal direction D1, and the second portion 300b′_CS1_B, which extends in a direction inclined in the second horizontal direction D2 with respect to the first horizontal direction D1. For example, the chip selection wires 300b′_CS may have a shape bending at least once in a plan view.

The plan view is a top view in the vertical direction (the Z direction).

In some embodiments, each of the semiconductor chips 200′ may include a plurality of pads 200′P, which may be divided into a plurality of chip selection pads 200′P_CS and a signal pad 200P_E. The pads 200′P of each of the semiconductor chips 200′ may be arranged on the top surface thereof.

The chip selection pads 200′P_CS of each of the semiconductor chips 200′ may be spaced apart from each other in the second horizontal direction D2. For example, the chip selection pads 200′P_CS of each of the semiconductor chips 200′ may be spaced apart from one of a plurality of chip selection substrate pads 100P_CS in the first horizontal direction D1.

The chip selection pads 200′P_CS of each of the semiconductor chips 200′ may be divided into a plurality of chip selection pad groups. For example, the chip selection pads 200′P_CS of each of the semiconductor chips 200′ may be included in one of the chip selection pad groups according to a chip selection substrate pad spaced apart from the chip selection pads 200′P_CS in the first horizontal direction D1.

In some embodiments, among the chip selection wires 300b′_CS, a first chip selection wire 300b′_CS1 including the first portion 300b′_CS1_A and the second portion 300b′_CS1_B may be electrically connected to chip selection pads included in different chip selection groups. For example, the first chip selection wire 300b′_CS1 may be electrically connected to two chip selection pads, which are on different semiconductor chips and spaced apart from each other in the first horizontal direction D1 and the second horizontal direction D2.

In the case where there are four semiconductor chips 200′, the unique identification signals of the semiconductor chips 200′ are described with reference to FIG. 17 and Table 6 below.

TABLE 6

| | | |
|---|---|---|
| Chip 4 | 0 | 0 |
| Chip 3 | 0 | 1 |
| Chip 2 | 1 | 0 |
| Chip 1 | 1 | 1 |
| | Pad 1 | Pad 2 |

The semiconductor chips 200′ may include first to fourth semiconductor chips 201′, 202′, 203′, and 204′. The first to fourth semiconductor chips 201′, 202′, 203′, and 204′ may be stacked sequentially offset in the first horizontal direction D1. For example, the first semiconductor chip 201′ may be at the bottom among the semiconductor chips 200′ and the fourth semiconductor chip 204′ may be at the top among the semiconductor chips 200′.

For example, when there are four semiconductor chips 200′, there may be two chip selection substrate pads 100P_CS, two chip selection pad groups, and two chip selection wires 300b′_CS.

In some embodiments, a plurality of chip selection pads of the second semiconductor chip 202′ may include a first chip selection pad P1 and a second chip selection pad P2. The first chip selection pad P1 and the second chip selection pad P2 may be spaced apart from each other in the second horizontal direction D2.

In some embodiments, a plurality of chip selection pads of the third semiconductor chip 203′ may include a third chip selection pad P3 and a fourth chip selection pad P4. The third chip selection pad P3 and the fourth chip selection pad P4 may be spaced apart from each other in the second horizontal direction D2.

The first chip selection pad P1 and the third chip selection pad P3 may be spaced apart from the first chip selection substrate pad 100P_CS1 in the first horizontal direction D1 and included in the first chip selection pad group 200′P_CS1. The second chip selection pad P2 and the fourth chip selection pad P4 may be spaced apart from the second chip selection substrate pad 100P_CS2 in the first horizontal direction D1 and included in the second chip selection pad group 200′P_CS2.

In other words, the third chip selection pad P3 may be spaced apart from the first chip selection pad P1 in the first horizontal direction D1 and the vertical direction (the Z direction). The fourth chip selection pad P4 may be spaced apart from the first chip selection pad P1 in the first horizontal direction D1, the second horizontal direction D2, and the vertical direction (the Z direction).

The chip selection wires 300b′_CS may include the first chip selection wire 300b′_CS1 and a second chip selection wire 300b′_CS2. The first chip selection wire 300b′_CS1 may be electrically connected to the first chip selection substrate pad 100P_CS1. The second chip selection wire 300b′_CS2 may be electrically connected to the second chip selection substrate pad 100P_CS2.

The first chip selection wire 300b′_CS1 may include the first portion 300b′_CS1_A and the second portion 300b′_CS1_B. For example, the first portion 300b′_CS1_A may be a portion of the first chip selection wire 300b′_CS1, which extends in the first horizontal direction D1 and the second portion 300b′_CS1_B may be a portion of the first chip selection wire 300b′_CS1, which extends in a direction inclined in the second horizontal direction D2 with respect to the first horizontal direction D1. For example, the first portion 300b′_CS1_A may electrically connect chip selection pads in the same chip selection pad group and the second portion 300b′_CS1_B may electrically connect chip selection pads included in different chip selection pad groups.

For example, the first portion 300b′_CS1_A of the first chip selection wire 300b′_CS1 may extend from the first chip selection substrate pad 100P_CS1 to the first chip selection pad P1 in the first horizontal direction D1. The second portion 300b′_CS1_B of the first chip selection wire 300b′_CS1 may extend from the first chip selection pad P1 to the fourth chip selection pad P4.

An end of the second chip selection wire 300b′_CS2 may be on the top surface of the first semiconductor chip 201′. For example, a chip selection pad, which is in the second chip selection pad group 200′P_CS2 and on the first semiconductor chip 201′, may be electrically connected to the second chip selection wire 300b′_CS2. A chip selection pad, which is in the second chip selection pad group 200′P_CS2 and on the third semiconductor chip 203′, may be electrically connected to the first chip selection wire 300b′_CS1.

Referring to Table 6, the unique identification signal of the first semiconductor chip 201′ is [11], the unique identification signal of the second semiconductor chip 202′ is [10], the unique identification signal of the third semiconductor chip 203′ is [01], and the unique identification signal of the fourth semiconductor chip 204′ is [00]. However, the unique identification signal of each semiconductor chip is not limited thereto.

The semiconductor package 4000 may form a unique identification signal of each of the semiconductor chips 200′ by combining the signal levels of a relatively small number of chip selection pads.

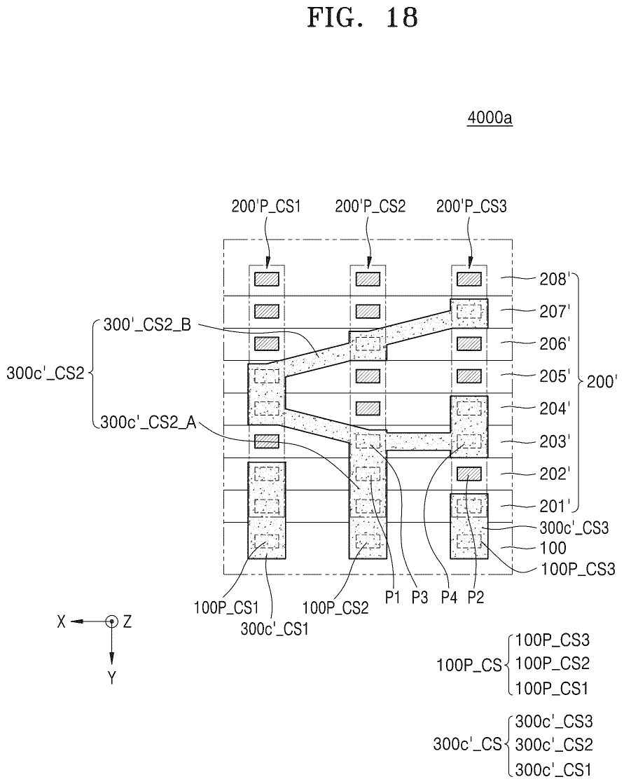

FIG. 18 is a schematic enlarged plan view of a chip selection pad portion of a semiconductor package 4000a, according to an example embodiment.

The semiconductor package 4000a of FIG. 18 and the semiconductor package 4000 of FIG. 17 differ in the number of semiconductor chips 200′. Redundant descriptions of the semiconductor package 4000a of FIG. 18 are omitted, and the semiconductor package 4000a of FIG. 18 is described below, focusing on the differences from the semiconductor package 4000 of FIG. 17.

The unique identification signal of each of a plurality of semiconductor chips 200′ and a plurality of chip selection wires 300c′_CS are described with reference to FIG. 18 and Table 7 below.

TABLE 7

| | | | |
|---|---|---|---|
| Chip 8 | 0 | 0 | 0 |
| Chip 7 | 0 | 0 | 1 |
| Chip 6 | 0 | 1 | 0 |
| Chip 5 | 1 | 0 | 0 |
| Chip 4 | 1 | 0 | 1 |
| Chip 3 | 0 | 1 | 1 |
| Chip 2 | 1 | 1 | 0 |
| Chip 1 | 1 | 1 | 1 |
| | Pad 1 | Pad 2 | Pad 3 |

The semiconductor chips 200′ may include first to eighth semiconductor chips 201′, 202′, 203′, 204′, 205′, 206′, 207′, and 208′. The first to eighth semiconductor chips 201′, 202′, 203′, 204′, 205′, 206′, 207′, and 208′ may be sequentially stacked. For example, the first semiconductor chip 201′ may be at the bottom among the semiconductor chips 200′ and the eighth semiconductor chip 208′ may be at the top among the semiconductor chips 200′.

A plurality of chip selection substrate pads 100P_CS of the package substrate 100 may include first to third chip selection substrate pads 100P_CS1, 100P_CS2, and 100P_CS3, which are spaced apart from each other in the second horizontal direction D2 (in FIG. 11).

A plurality of chip selection pads 200′P_CS (in FIG. 11) of the semiconductor chips 200′ may be divided into first to third chip selection pad groups 200′P_CS1, 200′P_CS2, and 200′P_CS3.

Each of the first to third chip selection pad groups 200′P_CS1, 200′P_CS2, and 200′P_CS3 may include one of a plurality of chip selection pads of each of the first to eighth semiconductor chips 201′, 202′, 203′, 204′, 205′, 206′, 207′, and 208′. In other words, each of the first to third chip selection pad groups 200′P_CS1, 200′P_CS2, and 200′P_CS3 may include eight chip selection pads.

The first to third chip selection pad groups 200′P_CS1, 200′P_CS2, and 200′P_CS3 may be spaced apart from the first to third chip selection substrate pads 100P_CS1, 100P_CS2, and 100P_CS3 in the first horizontal direction D1 (in FIG. 11). For example, chip selection pads in the first chip selection pad group 200′P_CS1 may be spaced apart from the first chip selection substrate pad 100P_CS1 in the first horizontal direction D1 (in FIG. 11).

The chip selection wires 300c′_CS may include a first chip selection wire 300c′_CS1, a second chip selection wire 300c′_CS2, and a third chip selection wire 300c′_CS3. The first chip selection wire 300c′_CS1 may be electrically connected to the first chip selection substrate pad 100P_CS1. The second chip selection wire 300c′_CS2 may be electrically connected to the second chip selection substrate pad 100P_CS2. The third chip selection wire 300c′_CS3 may be electrically connected to the third chip selection substrate pad 100P_CS3.

For example, there may be eight semiconductor chips 200′, three chip selection substrate pads 100P_CS, three chip selection pad groups, and three chip selection wires 300c′_CS.

Referring to FIG. 18, according to a plan view, the first chip selection wire 300c′_CS1 and the third chip selection wire 300c′_CS3 may extend in the first horizontal direction D1. The first chip selection wire 300c′_CS1 may be electrically connected to some of chip selection pads in the first chip selection pad group 200′P_CS1. The third chip selection wire 300c′_CS3 may be electrically connected to some of chip selection pads in the third chip selection pad group 200′P_CS3.

The second chip selection wire 300c′_CS2 may include a first portion 300c′_CS2_A, which extends in the first horizontal direction D1, and a second portion 300c′_CS2_B, which extends in a direction inclined in the second horizontal direction D2 with respect to the first horizontal direction D1. In some embodiments, the second chip selection wire 300c′_CS2 may be electrically connected to at least two chip selection pads among a plurality of chip selection pads 200′P_CS (in FIG. 16) included in one semiconductor chip.

In some embodiments, a plurality of chip selection pads of the second semiconductor chip 202′ may include a first chip selection pad P1 and a second chip selection pad P2. The first chip selection pad P1 and the second chip selection pad P2 may be spaced apart from each other in the second horizontal direction D2.

In some embodiments, a plurality of chip selection pads of the third semiconductor chip 203′ may include a third chip selection pad P3 and a fourth chip selection pad P4. The third chip selection pad P3 and the fourth chip selection pad P4 may be spaced apart from each other in the second horizontal direction D2.

The first chip selection pad P1 and the third chip selection pad P3 may be spaced apart from the second chip selection substrate pad 100P_CS2 in the first horizontal direction D1. The second chip selection pad P2 and the fourth chip selection pad P4 may be spaced apart from the third chip selection substrate pad 100P_CS3 in the first horizontal direction D1.

In some embodiments, the second chip selection wire 300c′_CS2 may be electrically connected to the first chip selection pad P1, the third chip selection pad P3, and the fourth chip selection pad P4. For example, the first chip selection pad P1 and the third chip selection pad P3 may be connected by a portion of the first portion 300c′_CS2_A of the second chip selection wire 300c′_CS2, and the third chip selection pad P3 and the fourth chip selection pad P4 may be connected by a portion of the second portion 300c′_CS2_B of the second chip selection wire 300c′_CS2.

The second chip selection wire 300c′_CS2 may electrically connect a chip selection pad, which is in the first chip selection pad group 200′P_CS1 and included in the fourth semiconductor chip 204′, to a chip selection pad, which is in the second chip selection pad group 200′P_CS2 and included in the third semiconductor chip 203′.

Not only the second chip selection wire 300c′_CS2 but also other chip selection wires 300c′_CS may be electrically connected to chip selection pads in different chip selection pad groups according to the unique identification signals of the semiconductor chips 200′.

Referring to Table 7, the unique identification signal of the first semiconductor chip 201′ is [111], the unique identification signal of the second semiconductor chip 202′ is [110], the unique identification signal of the third semiconductor chip 203′ is [011], the unique identification signal of the fourth semiconductor chip 204′ is [101], the unique identification signal of the fifth semiconductor chip 205′ is [100], the unique identification signal of the sixth semiconductor chip 206′ is [010], the unique identification signal of the seventh semiconductor chip 207′ is [001], and the unique identification signal of the eighth semiconductor chip 208′ is [000]. However, the unique identification signal of each semiconductor chip is not limited thereto.

While the inventive concept has been particularly shown and described with reference to embodiments thereof, it will be understood that various changes in form and details may be made therein without departing from the spirit and scope of the following claims.

1. A semiconductor package comprising:
a package substrate;
a stack structure on the package substrate and including a plurality of semiconductor chips stacked sequentially and offset from each other; and
a plurality of chip selection wires configured to respectively electrically connect the package substrate to the plurality of semiconductor chips of the stack structure,
wherein each of the plurality of semiconductor chips includes a plurality of chip selection pads,
wherein each of the plurality of chip selection wires extends from the package substrate to one of the plurality of semiconductor chips along side and top surfaces of the stack structure, and
wherein extension lengths of the plurality of chip selection wires are different from each other.

2. The semiconductor package of claim 1,
wherein the package substrate includes a plurality of chip selection substrate pads on a top surface of the package substrate,
wherein the plurality of chip selection pads are on top surfaces of the plurality of semiconductor chips,
wherein respective one ends of the plurality of chip selection wires are on the top surface of the package substrate, and
wherein respective other ends of the plurality of chip selection wires are respectively on the top surfaces of different semiconductor chips.

3. The semiconductor package of claim 1,
wherein the stack structure has a first side surface and a second side surface adjacent to the first side surface,
wherein the plurality of chip selection wires are in contact with the first side surface of the stack structure, and
wherein an extension length of each of the plurality of chip selection wires decreases toward the second side surface of the stack structure.

4. The semiconductor package of claim 1,
wherein the plurality of semiconductor chips are stacked sequentially and offset in a first horizontal direction,
wherein the plurality of chip selection pads of each of the plurality of semiconductor chips are spaced apart from each other in a second horizontal direction that is perpendicular to the first horizontal direction,
wherein the plurality of chip selection wires are spaced apart from each other in the second horizontal direction, and
wherein the plurality of chip selection wires are respectively and electrically connected to different chip selection pads among the plurality of chip selection pads of one of the plurality of semiconductor chips.

5. The semiconductor package of claim 1, wherein the plurality of semiconductor chips are electrically connected to different numbers of the plurality of chip selection wires.

6. The semiconductor package of claim 5,
wherein the plurality of semiconductor chips includes a first semiconductor chip and a second semiconductor chip on the first semiconductor chip, and
wherein a number of chip selection wires electrically connected to the first semiconductor chip among the plurality of chip selection wires is greater than a number of chip selection wires electrically connected to the second semiconductor chip among the plurality of chip selection wires.

7. The semiconductor package of claim 1,
wherein a number of the plurality of semiconductor chips of the stack structure is N, where N is a natural number of at least 2,
wherein a number of the plurality of chip selection pads of each of the plurality of semiconductor chips is N−1, and
wherein a number of the plurality of chip selection wires is N−1.

8. The semiconductor package of claim 7,
wherein a number of chip selection wires connected to a bottommost semiconductor chip among the plurality of semiconductor chips is N−1,
wherein the plurality of semiconductor chips includes a first semiconductor chip and a second semiconductor chip on the first semiconductor chip, and
wherein a number of chip selection wires electrically connected to the second semiconductor chip is one less than a number of chip selection wires electrically connected to the first semiconductor chip.

9. The semiconductor package of claim 1,
wherein the plurality of semiconductor chips includes a first semiconductor chip,
wherein an end of a first chip selection wire among the plurality of chip selection wires is on a top surface of the first semiconductor chip, and
wherein the first chip selection wire is electrically connected to the first semiconductor chip and to every semiconductor chip between the first semiconductor chip and the package substrate.

10. The semiconductor package of claim 9,
wherein the plurality of semiconductor chips are stacked and offset in a first horizontal direction, and
wherein the first chip selection wire extends in the first horizontal direction along the top surface of the stack structure and in a vertical direction along the side surface of the stack structure.

11. The semiconductor package of claim 1, further comprising:
a signal wire configured to electrically connect the package substrate to the plurality of semiconductor chips and extending along the side and top surfaces of the stack structure,
wherein an extension length of the signal wire is greater than the extension lengths of the plurality of chip selection wires.

12. The semiconductor package of claim 11, wherein the plurality of chip selection wires conformally extend along the side and top surfaces of the stack structure.

13. A semiconductor package comprising:
a package substrate;
a lower stack structure on the package substrate and including a plurality of lower semiconductor chips stacked sequentially and offset in a first horizontal direction;
an upper stack structure on the lower stack structure and including a plurality of upper semiconductor chips stacked sequentially and offset in an opposite direction to the first horizontal direction;
a support chip on the package substrate and in contact with a bottom surface of the upper stack structure;
a plurality of lower chip selection wires configured to electrically connect the package substrate to the plurality of lower semiconductor chips of the lower stack structure; and
a plurality of upper chip selection wires configured to electrically connect the package substrate to the plurality of upper semiconductor chips of the upper stack structure,
wherein the upper stack structure is offset from the lower stack structure in the first horizontal direction,
wherein each of the plurality of lower chip selection wires extends from the package substrate to one of the plurality of lower semiconductor chips along side and top surfaces of the lower stack structure, and
wherein each of the plurality of upper chip selection wires extends from the package substrate to one of the plurality of upper semiconductor chips along an outer surface of the support chip and side and top surfaces of the upper stack structure.

14. The semiconductor package of claim 13,
wherein a first side surface of a bottommost upper semiconductor chip among the plurality of upper semiconductor chips does not overlap the lower stack structure in a vertical direction, and
wherein the first side surface of the bottommost upper semiconductor chip is coplanar with a first side surface of the support chip.

15. The semiconductor package of claim 14, wherein the plurality of upper chip selection wires extend in the vertical direction along the first side surface of the bottommost upper semiconductor chip and the first side surface of the support chip.

16. The semiconductor package of claim 13,
wherein extension lengths of the plurality of lower chip selection wires are different from each other, and
wherein extension lengths of the plurality of upper chip selection wires are different from each other.

17. The semiconductor package of claim 13,
wherein the plurality of lower chip selection wires are electrically connected to different numbers of lower semiconductor chips among the plurality of lower semiconductor chips, and
wherein the plurality of upper chip selection wires are electrically connected to different numbers of upper semiconductor chips among the plurality of upper semiconductor chips.

18. The semiconductor package of claim 13,
wherein respective one ends of the plurality of lower chip selection wires are on top surfaces of different lower semiconductor chips among the plurality of lower semiconductor chips, and
wherein respective one ends of the plurality of upper chip selection wires are on top surfaces of different upper semiconductor chips among the plurality of upper semiconductor chips.

19. The semiconductor package of claim 18,
wherein the plurality of lower semiconductor chips includes a first lower semiconductor chip,
wherein the one end of a first lower chip selection wire among the plurality of lower chip selection wires is on a top surface of the first lower semiconductor chip,
wherein the first lower chip selection wire is electrically connected to every lower semiconductor chip between the first lower semiconductor chip and the package substrate,
wherein the plurality of upper semiconductor chips includes a first upper semiconductor chip,
wherein the one end of a first upper chip selection wire among the plurality of upper chip selection wires is on a top surface of the first upper semiconductor chip, and
wherein the first upper chip selection wire is electrically connected to every upper semiconductor chip between the first upper semiconductor chip and the package substrate.

20. (canceled)

21. A semiconductor package comprising:
a package substrate;
a stack structure on the package substrate and including a plurality of semiconductor chips stacked sequentially and offset in a first horizontal direction;
an insulating cover on a top surface of the stack structure; and
a plurality of chip selection wires configured to electrically connect the package substrate to the plurality of semiconductor chips of the stack structure,
wherein each of the plurality of semiconductor chips includes a plurality of chip selection pads on a top surface thereof,
wherein the insulating cover covers at least one of the plurality of chip selection pads of the plurality of semiconductor chips, a top surface of the insulating cover is in contact with at least one of the plurality of chip selection wires, and
wherein each of the plurality of chip selection wires extends from the package substrate to one of the plurality of semiconductor chips along side and top surfaces of the stack structure.

22.-30. (canceled)
